(19) United States
(12) Patent Application Publication
(10) Pub. No.: US 2025/0098264 A1
(43) Pub. Date: Mar. 20, 2025

(54) SEMICONDUCTOR DEVICE

(71) Applicant: SAMSUNG ELECTRONICS CO., LTD., Suwon-si (KR)

(72) Inventors: Sangcheol NA, Suwon-si (KR); Beomjin KIM, Suwon-si (KR); Yoolim AHN, Suwon-si (KR); Kyoungwoo LEE, Suwon-si (KR); Minseung LEE, Suwon-si (KR); Hyeryeong LEE, Suwon-si (KR); Keun Hwi CHO, Suwon-si (KR); Seungseok HA, Suwon-si (KR)

(73) Assignee: SAMSUNG ELECTRONICS CO., LTD., Suwon-si (KR)

(21) Appl. No.: 18/604,031

(22) Filed: Mar. 13, 2024

(30) Foreign Application Priority Data
Sep. 14, 2023 (KR) 10-2023-0122775

(51) Int. Cl. H01L 29/417; H01L 27/088; H01L 29/06; H01L 29/423; H01L 29/775; H01L 29/786

(52) U.S. Cl. CPC H10D 64/254; H10D 30/43; H10D 30/6735; H10D 30/6757; H10D 62/121; H10D 84/0149; H10D 84/0151; H10D 84/038; H10D 84/83

(57) ABSTRACT

A semiconductor device includes an insulating layer including a first surface, a second surface, and an element isolation trench, an insulating pattern on the first surface of the insulating layer, an active pattern on the insulating pattern and including channel patterns, a source/drain pattern on at least one side of the active pattern, a lower wiring structure on the second surface of the insulating layer, and a through-via that extending in the insulating layer and connecting the source/drain pattern and the lower wiring structure, where the insulating pattern may include a first portion between the insulating layer and the active pattern, a second portion surrounding at least a portion of the through-via, and a third portion on a bottom surface of the element isolation trench.

### CROSS-REFERENCE TO RELATED APPLICATION

This application is based on and claims priority to Korean Patent Application No. 10-2023-0122775 filed on Sep. 14, 2023, in the Korean Intellectual Property Office, the disclosure of which is incorporated herein by reference in its entirety.

### BACKGROUND

Example embodiments of the disclosure relate to a semiconductor device.

Semiconductor materials are materials falling within the intermediate category between conductors and nonconductors, may refer to materials conducting electricity under predetermined conditions. Such semiconductor materials may be used to manufacture various semiconductor devices, such as memory devices. These semiconductor devices may be used in various electronic devices.

The demands for the characteristics of semiconductor devices have been gradually increasing. For example, the demands for semiconductor devices with higher reliability, higher speed, and/or more functions have been gradually increasing. In order to obtain these required characteristics, the structures in semiconductor devices have gradually become complicated and have been integrated at higher densities.

Information disclosed in this Background section has already been known to or derived by the inventors before or during the process of achieving the embodiments of the present application, or is technical information acquired in the process of achieving the embodiments. Therefore, it may include information that does not form the prior art that is already known to the public.

### SUMMARY

One or more example embodiments provide a semiconductor device with improved reliability.

Additional aspects will be set forth in part in the description which follows and, in part, will be apparent from the description, or may be learned by practice of the presented embodiments.

According to an aspect of an example embodiment, a semiconductor device may include an insulating layer including a first surface, a second surface, and an element isolation trench, an insulating pattern on the first surface of the insulating layer, an active pattern on the insulating pattern and including a channel pattern, a source/drain pattern on at least one side of the active pattern, a lower wiring structure on the second surface of the insulating layer, and a through-via that extending in the insulating layer and connecting the source/drain pattern and the lower wiring structure, where the insulating pattern may include a first portion between the insulating layer and the active pattern, a second portion surrounding at least a portion of the through-via, and a third portion on a bottom surface of the element isolation trench.

According to an aspect of an example embodiment, a semiconductor device may include an insulating layer including a first surface and a second surface, an insulating pattern on the first surface of the insulating layer, an active pattern on the insulating pattern and including a channel pattern, a source/drain pattern on at least one side of the active pattern, a dummy source/drain pattern extending in at least a portion of the insulating pattern and positioned below the source/drain pattern, a lower wiring structure below the second surface of the insulating layer, and a through-via extending in the insulating layer and connecting the source/drain pattern and the lower wiring structure, where the insulating pattern may include a first portion between the insulating layer and the active pattern, a second portion surrounding at least a portion of the through-via, and a fourth portion at least partially surrounding the dummy source/drain pattern.

According to an aspect of an example embodiment, a semiconductor device may include an insulating layer including a first surface, a second surface, and an element isolation trench, an insulating pattern on the first surface of the insulating layer, an active pattern on the insulating pattern and including a channel pattern, a source/drain pattern on at least one side of the active pattern, a dummy source/drain pattern extending in at least a portion of the insulating pattern and below the source/drain pattern, a gate electrode on the insulating pattern and at least partially surrounding the channel pattern, a lower wiring structure below the second surface of the insulating layer, and a through-via extending in the insulating layer and connecting the source/drain pattern and the lower wiring structure, where the insulating pattern may include a first portion between the insulating layer and the gate electrodes, a second portion surrounding at least a portion of the through-via, a third portion on inner walls and bottom surfaces of the element isolation trench, and a fourth portion at least partially surrounding the dummy source/drain pattern, and where the through-via may include a first via portion at least partially surrounded by the second portion of the insulating pattern, and a second via portion between the first via portion and the lower wiring structure.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a plan view illustrating a semiconductor device according to one or more example embodiments;

FIG. 2 is a cross-sectional view taken along line A-A′ in FIG. 1 according to one or more example embodiments;

FIG. 3 is a cross-sectional view taken along line B-B′ in FIG. 1 according to one or more example embodiments;

FIG. 4 is an enlarged cross-sectional view of a S1 region in FIG. 2 according to one or more example embodiments;

FIGS. 5 to 8 are cross-sectional views of portions of semiconductor devices corresponding to the S1 region in FIG. 2 according to one or more example embodiments;

FIG. 9 is a cross-sectional view illustrating a semiconductor device according to one or more example embodiments; and

FIGS. 10 to 27 are cross-sectional views illustrating a method of manufacturing a semiconductor device according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

In addition, the size and thickness of each configuration shown in the drawings are arbitrarily shown for understanding and ease of description, but the disclosure is not limited thereto. In the drawings, the thickness of layers, films, panels, regions, etc., may be exaggerated for clarity. In the drawings, for understanding and ease of description, the thickness of some layers and areas is exaggerated.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

In addition, unless explicitly described to the contrary, the word “comprise”, and variations such as “comprises” or “comprising”, will be understood to imply the inclusion of stated elements but not the exclusion of any other elements.

In the semiconductor devices according to one or more example embodiments for example, transistors may have a gate-all-around (GAA) field effect transistor (FET) (GAAFET) structure, a multi-bridge-channel FET (MBCFET™) structure, or the like in which four sides of each channel are surrounded by a gate electrode. However, the present disclosure is not limited thereto, and transistors may be formed in a FinFET structure, or may be formed in a three-dimensional stack FET (3DSFET) structure, a complementary FET (CFET) structure, or the like, according to various technologies.

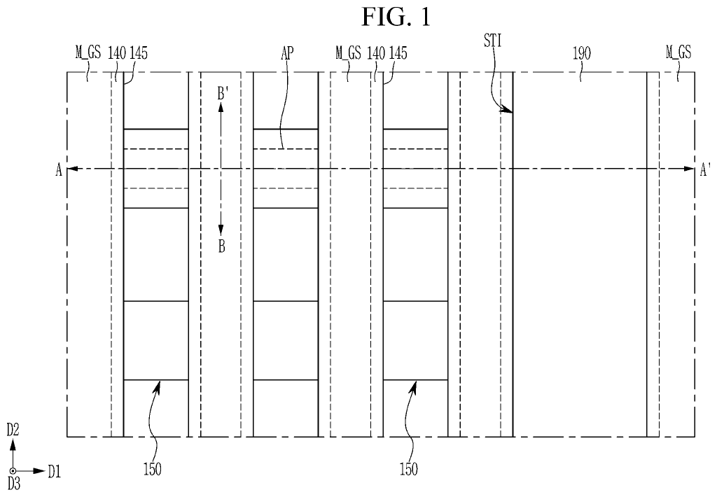

Hereinafter, a semiconductor device according to an embodiment will be described with reference to FIG. 1 to FIG. 4.

Throughout the specification, a singular component and a component provided in a plurality may be referred to interchangeably as a singular form and/or plural form.

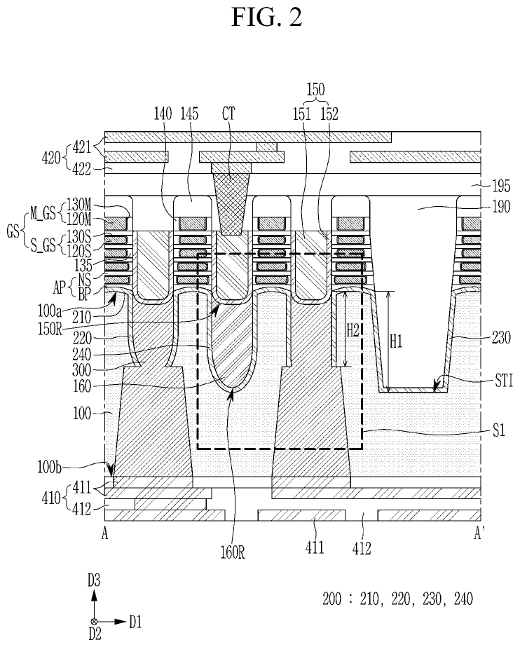

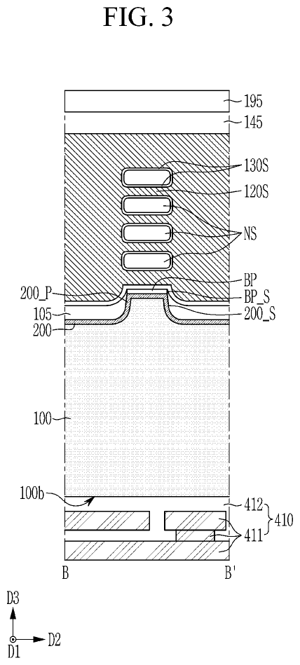

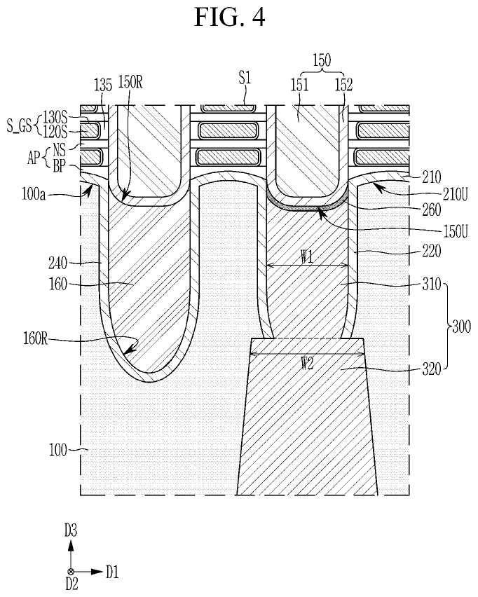

FIG. 1 is a plan view illustrating a semiconductor device according to one or more example embodiments. FIG. 2 is a cross-sectional view taken along line A-A′ in FIG. 1 according to one or more example embodiments. FIG. 3 is a cross-sectional view taken along line B-B′ in FIG. 1 according to one or more example embodiments. FIG. 4 is an enlarged cross-sectional view of a S1 region in FIG. 2 according to one or more example embodiments.

First, referring to FIG. 1 to FIG. 3, a semiconductor device according to some embodiments may include an insulating layer 100, an insulating pattern 200, an active pattern AP, a field insulating layer 105, a gate structure GS, a source/drain pattern 150, a dummy source/drain pattern 160, a lower wiring structure 410, and a through-via 300.

The insulating layer 100 may include, for example, a film formed of silicon oxide (SiO₂), silicon nitride (SiN), silicon oxynitride (SiON), or a combination thereof. In the drawings, the insulating layer 100 is shown as a single layer; however, this is merely for ease of explanation, and multiple insulating layers may be provided. The insulating layer 100 may have an element isolation trench STI.

The insulating layer 100 may have a first surface 100a and a second surface 100b.

The first surface 100a and the second surface 100b of the insulating layer 100 may be flat surfaces parallel with a first direction D1 and a second direction D2 intersecting the first direction D1. The first surface 100a of the insulating layer 100 may be opposite to the second surface 100b in a third direction D3. The first surface 100a of the insulating layer 100 may be referred to as the front side or upper surface of the insulating layer 100. The second surface 100b of the insulating layer 100 may be referred to as the back side or lower surface of the insulating layer 100. In some embodiments, logic circuits in a cell area may be implemented on the first surface 100a of the insulating layer 100.

The insulating pattern 200 may be positioned on the first surface 100a of the insulating layer 100. The insulating pattern 200 may be vertically below the lower patterns BP (to be described below) in the third direction D3 (for example, the thickness direction of the insulating layer 100). The insulating pattern 200 may be vertically below a plurality of channel patterns NS (to be described below) in the third direction D3. The insulating pattern 200 may be vertically below the gate structure GS (to be described below) in the third direction D3 (for example, the thickness direction of the insulating layer 100).

In an embodiment, the insulating pattern 200 may be positioned between the first surface 100a of the insulating layer 100 and the lower patterns BP. Further, the insulating pattern 200 may surround at least a portion of the through-via 300. The insulating pattern 200 may be positioned between the insulating layer 100 and the through-via 300. Further, the insulating pattern 200 may be positioned in the element isolation trench STI in the insulating layer 100. In other words, the insulating pattern 200 may be positioned between the insulating layer 100 and interlayer insulating layers 190. Furthermore, the insulating pattern 200 may surround the dummy source/drain pattern 160. The insulating pattern 200 may be positioned between the insulating layer 100 and the dummy source/drain pattern 160.

Accordingly, the insulating pattern 200 may include a first portion 210 positioned between the lower patterns BP and the insulating layer 100, a second portion 220 surrounding at least a portion of the through-via 300, a third portion 230 positioned on the inner walls and bottom surfaces of the element isolation trench STI, and a fourth portion 240 that surround the dummy source/drain pattern 160. In this case, the first to fourth portions 210 to 240 of each insulating pattern 200 may be integrally formed without any interfaces; however, the present disclosure is not limited thereto. A detailed description of the first to fourth portions 210 to 240 of the insulating pattern 200 will be made below with reference to FIG. 4.

The insulating pattern 200 may include various insulating materials. The insulating pattern 200 may include a material having etch selectivity to the insulating layer 100. For example, the insulating pattern 200 may include at least one of silicon nitride (SiN), silicon oxynitride (SiON), silicon carbonitride (SiCN), silicon oxycarbide (SiOC), and silicon oxycarbonitride (SiOCN). Alternatively, outer insulating pattern 200E may include a metal oxide or a metal nitride, such as aluminum oxide (Al₂O₃) or aluminum nitride (AlN).

The active pattern AP may be positioned on the insulating pattern 200. The active pattern AP may extend in the first direction D1. As an example, the active pattern AP may be positioned in areas where p-type metal-oxide-semiconductors (MOSs) (PMOSs) are formed. As another example, the active pattern AP may be positioned in areas where n-type MOSs (NMOSs) are formed.

The active pattern AP may be multi-channel active pattern. The active pattern AP may include the lower pattern BP and the plurality of channel patterns NS. In an embodiment, the lower pattern BP and the plurality of channel patterns NS may have a nanosheet shape, and may be semiconductor patterns including a semiconductor material. The lower pattern BP may be positioned on the insulating layer 100. The lower pattern BP may extend in the first direction D1.

The plurality of channel patterns NS may be positioned on the upper surface of the lower patterns BP. The plurality of channel patterns NS may be spaced apart from the lower patterns BP in the third direction D3. The plurality of channel patterns NS may be arranged at intervals in the third direction D3. The third direction D3 may be a direction intersecting the first direction D1 and the second direction D2. For example, the third direction D3 may be the thickness direction of the insulating layer 100. The second direction D2 may be a direction intersecting the first direction D1.

In FIG. 2 and FIG. 3, it is shown that, along the third direction D3, four channel patterns NS are stacked so as to be apart from one another; however, this is merely for ease of explanation, and the present disclosure is not limited thereto. For example, fewer than four or more than four channel patterns NS may be stacked along the third direction D3 so as to be apart from one another.

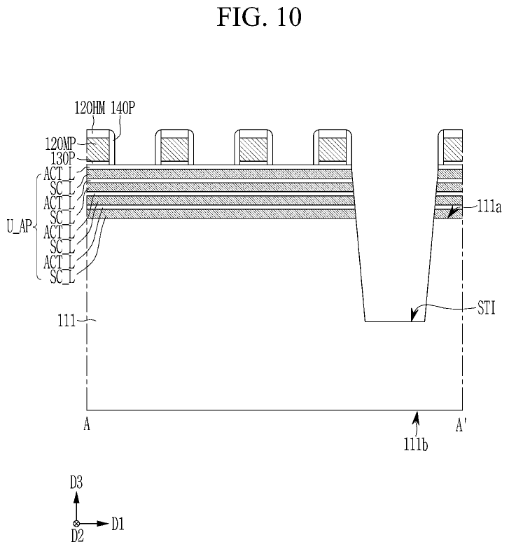

The lower pattern BP may be patterns formed by etching at least a portion of a substrate 111 (FIG. 10), and may include epitaxial layers grown from the substrate 111. The lower pattern BP may include silicon (Si) or germanium (Ge) which is an elemental semiconductor material. Also, the lower pattern BP may include a compound semiconductor, and may include, for example, a IV-IV compound semiconductor or a III-V compound semiconductor.

The IV-IV compound semiconductor may be, for example, a binary compound, or a ternary compound including at least two of carbon (C), silicon (Si), germanium (Ge), and tin (Sn).

The III-V compound semiconductor may be, for example, one of binary compounds, ternary compounds, and quaternary compounds which are formed by bonding of at least one of aluminum (Al), gallium (Ga), and indium (In) which are group III elements and one of phosphorus (P), arsenic (As), and antimony (Sb) which are group V elements.

The plurality of channel patterns NS may include one of silicon (Si) and silicon germanium (SiGe) which are elemental semiconductor materials, IV-IV compound semiconductors, and III-V compound semiconductors. Each of the plurality of channel patterns NS may include the same material as that in the lower pattern BP, and may include a material different from that in the lower pattern BP.

In an embodiment, the lower pattern BP and the plurality of channel patterns NS may include silicon (Si). As another example, the lower pattern BP and the plurality of channel patterns NS may include silicon germanium (SiGe). As yet another example, the lower pattern BP may include silicon (Si), and the plurality of channel patterns NS may include silicon germanium (SiGe).

The field insulating layer 105 may be positioned on the insulating pattern 200. The field insulating layer 105 may cover the side surface 200_S of at least one protrusion 200_P of the insulating pattern 200. The at least one protrusion 200_P of the insulating pattern 200 may refer to portions of the insulating pattern 200 protruding in the third direction D3 from the upper surface of the insulating layer 100. In other words, in an embodiment, the side surface 200_S of the at least one protrusion 200_P of the insulating pattern 200 may refer to the side surface of the portions of the insulating pattern 200 protruding in the third direction D3 from the upper surface of the insulating layer 100. Accordingly, the field insulating layer 105 may extend over the at least one protrusion 200_P of the insulating pattern 200 in the second direction D2. Further, the field insulating layer 105 may not be positioned on the portions of the insulating pattern 200 that are vertically below the lower pattern BP in the third direction D3. In other words, the field insulating layer 105 may not be positioned between the insulating pattern 200 and the lower pattern BP.

Further, the field insulating layer 105 may be positioned on the side walls BP_S of the lower pattern BP. As an example, the field insulating layer 105 may entirely cover the side walls BP_S of the lower pattern BP. Accordingly, the field insulating layer 105 may be vertically below the lower pattern BP in the third direction D3.

In FIG. 3, it is shown that the field insulating layer 105 entirely covers the side walls BP_S of the lower pattern BP; however, the present disclosure is not limited thereto. For example, the field insulating layer 105 may cover at least a portion of the side walls BP_S of the lower pattern BP. In other words, at least a portion of the side walls BP_S of the lower pattern BP may be covered by the field insulating layer 105, and the other portions of the side walls BP_S of the lower pattern BP may be covered by the gate structure GS to be described below. In this case, the lower pattern BP may extend over the gate structure GS in the second direction D2.

Alternatively, as another example, the field insulating layer 105 may not be positioned on the side walls BP_S of the lower pattern BP. In other words, the field insulating layer 105 may be positioned on the side surface 200_S of the at least one protrusion 200_P of the insulating pattern 200, and the gate structure GS may be positioned on the side walls BP_S of the lower pattern BP. In this case, the field insulating layer 105 may not extend over the lower pattern BP in the second direction D2. As yet another example, the gate structure GS may cover the entire side surface of the lower pattern BP extending in the second direction D2 and at least a portion of the upper portions of the side surface 200_S of the at least one protrusion 200_P of the insulating pattern 200, and the field insulating layer 105 may cover at least a portion of the side surface 200_S of the at least one protrusion 200_P of the insulating pattern 200. In this case, at least a portion of the at least one protrusion 200_P of the insulating pattern 200 may extend over the field insulating layer 105 in the second direction D2, and the other portions of the at least one protrusion 200_P of the insulating pattern 200 may extend over the gate structure GS in the second direction D2.

The field insulating layer 105 may include, for example, a film formed of an oxide, a nitride, an oxynitride, or a combination thereof. In the drawings, the field insulating layer 105 is shown as a single layer; however, this is merely for ease of explanation, and the field insulating layers are not limited thereto.

The gate structure GS may be positioned on the insulating layer 100. The gate structure GS may extend in the second direction D2. Multiple gate structures GS may be positioned apart from one another in the first direction D1.

The gate structure GS may be positioned on the active pattern AP. The gate structure GS may intersect the active pattern AP. Multiple gate structures GS may surround the plurality of channel patterns NS, respectively.

The gate structure GS may include a plurality of sub-gate structure S_GS and main gate structure M_GS. The plurality of sub-gate structures S_GS may be positioned between every two channel patterns adjacent to each other in the third direction D3 among the plurality of channel patterns NS and between the lower pattern BP and the lowermost channel patterns NS. The main gate structure M_GS may be positioned on the uppermost channel patterns NS.

Specifically, the plurality of sub-gate structures S_GS may be positioned between the upper surface of the lower pattern BP and the lower surface of the lowermost channel patterns NS and between the upper surface of the channel patterns NS and the lower surface of the channel patterns NS facing each other in the third direction D3. The plurality of sub-gate structures S_GS may be adjacent to the source/drain pattern 150 to be described below. The main gate structure M_GS may be positioned on the plurality of sub-gate structures S_GS and the channel patterns NS.

According to an embodiment, each of the active patterns AP may include a plurality of channel patterns NS, and each of the gate structures GS may include a plurality of sub-gate structures S_GS. In this case, the number of the plurality of sub-gate structures S_GS may be proportional to the number of the plurality of channel patterns NS included in the active pattern AP.

For example, the number of the plurality of sub-gate structures S_GS may be the same as the number of the plurality of channel patterns NS. As an example, as shown in FIG. 3 and FIG. 4, the number of the plurality of sub-gate structures S_GS may be four. However, the number of the plurality of sub-gate structures S_GS is not limited thereto, and each active layer may include three or less, or five or more sub-gate structures S_GS.

Each of the plurality of sub-gate structures S_GS may include a sub-gate electrode 120S and a sub-gate insulating layer 130S.

The sub-gate electrode 120S may be formed on a lower pattern BP. The sub-gate electrode 120S may intersect the lower pattern BP. The sub-gate electrode 120S may surround a plurality of channel patterns NS.

At least a portion of the sub-gate electrode 120S may be positioned on a structure in which another sub-gate electrode 120S and a plurality of channel patterns NS are stacked. The other portion of the sub-gate electrode 120S may be formed so as to cover both side surfaces of the structure in which another sub-gate electrode 120S and the plurality of channel patterns NS are stacked. In this case, four sides of the plurality of channel patterns NS may be surrounded by the sub-gate electrode 120S.

The sub-gate electrode 120S may include at least one of metals, metal alloys, conductive metal nitrides, metal silicides, doped semiconductor materials, conductive metal oxides, and conductive metal oxynitrides. The sub-gate electrode 120S may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (AI), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but are not limited thereto. The conductive metal oxides and the conductive metal oxynitrides may include the oxides of the above-mentioned materials, but are not limited thereto.

The sub-gate insulating layer 130S may extend along the upper surface of a lower pattern BP. The sub-gate insulating layer 130S may be positioned along the perimeter of the plurality of channel patterns NS. The sub-gate insulating layer 130S may directly contact the lower pattern BP, an inner gate spacer 135, and the plurality of channel patterns NS. The sub-gate insulating layer 130S may be interposed between the plurality of channel patterns NS and the sub-gate electrode 120S. Further, the sub-gate insulating layer 130S may extend along the upper surface of a field insulating layer 105. The sub-gate insulating layer 130S may include various insulating materials.

In an embodiment, each sub-gate insulating layer 130S is shown as a single layer in the drawings, but is not limited thereto. For example, each sub-gate insulating layer 130S may include multiple layers including silicon oxide (SiO₂) and a high-dielectric constant material. In this case, the high-dielectric constant material may include a material having a dielectric constant higher than that of silicon oxide (SiO₂), such as hafnium oxide (HfO), aluminum oxide (AlO), or tantalum oxide (TaO).

Each main gate structure M_GS may be positioned on a sub-gate structure S_GS and a plurality of channel patterns NS. The main gate structure M_GS may be positioned on the upper surface of the plurality of channel patterns NS.

The main gate structure M_GS may include a main gate electrode 120M and a main gate insulating layer 130M.

The main gate electrode 120M may be positioned on a sub-gate structure S_GS and the plurality of channel patterns NS. The main gate electrode 120M may be positioned on the upper surface of the plurality of channel patterns NS. The main gate electrode 120M may include the same material as that in the sub-gate electrode 120S. For example, the main gate electrode 120M may include at least one of metals, metal alloys, conductive metal nitrides, metal silicides, doped semiconductor materials, conductive metal oxides, and conductive metal oxynitrides.

The main gate insulating layer 130M may extend along the side surface of the main gate electrode 120M. The main gate insulating layer 130M may extend along the side surface of a gate spacer 140. The main gate insulating layer 130M may include various insulating materials.

In an embodiment, each main gate insulating layer 130M is shown as a single layer in the drawings, but is not limited thereto. For example, each main gate insulating layer 130M may include multiple layers including silicon oxide (SiO₂) and a high-dielectric constant material. In this case, the high-dielectric constant material may include a material having a dielectric constant higher than that of silicon oxide (SiO₂), such as hafnium oxide (HfO), aluminum oxide (AlO), or tantalum oxide (TaO).

The semiconductor device according to some embodiments may further include inner gate spacers 135, gate spacers 140, and capping layers 145.

The inner gate spacers 135 may be positioned on the side surface of the sub-gate structure S_GS. For example, the inner gate spacers 135 may be positioned between the source/drain pattern 150 and the sub-gate structure S_GS. The inner gate spacers 135 may not be positioned on the side surface of the main gate structure M_GS.

The gate spacers 140 may be positioned on the side surface of the main gate electrodes 120M. The gate spacers 140 may not be disposed between the lower pattern BP and the plurality of channel patterns NS. The gate spacers 140 may not be disposed between a plurality of channel patterns NS adjacent to each other in the third direction D3.

The gate spacers 140 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof. In the drawings, each gate spacer 140 is shown as a single layer; however, this is merely for ease of explanation, and the gate spacers are not limited thereto.

The capping layers 145 may be positioned on the main gate structure M_GS and the gate spacers 140. The upper surface of the capping layers 145 may be positioned together with the upper surface of the interlayer insulating layers 190 in the same plane. Unlike those shown in the drawings, the capping layers 145 may be positioned between the gate spacers 140.

The capping layers 145 may include, for example, at least one of silicon nitride (SiN), silicon oxynitride (SiON), silicon (Si), silicon carbonitride (SiCN), silicon oxycarbonitride (SiOCN), and combinations thereof. The capping layers 145 may include a material having etch selectivity to the interlayer insulating layers 190.

The source/drain pattern 150 may be positioned on both sides of each of the sub-gate structure S_GS. The source/drain pattern 150 may contact the side surface of the channel patterns NS and the side surface of the inner gate spacers 135. The source/drain pattern 150 may be coupled to the channel patterns NS. In an embodiment, the source/drain pattern 150 may be coupled to the dummy source/drain pattern 160 or the through-via 300. For example, some of the source/drain patterns 150 may be coupled to the dummy source/drain pattern 160 to be described below, and the others of the source/drain patterns 150 may be coupled to the through-via 300 to be described below.

The source/drain pattern 150 may be positioned in source/drain recesses 150R extending along the third direction D3. The source/drain recesses 150R may be filled with the source/drain pattern 150. The bottom surfaces of the source/drain recesses 150R may be defined by the dummy source/drain pattern 160 or the through-via 300. The side surface of the source/drain recesses 150R may be defined by the inner gate spacers 135 and the active pattern AP.

In an embodiment, the lower surface 150U of the source/drain pattern 150 may be positioned at a level lower than the lower surface of the plurality of sub-gate structures S_GS. For example, as shown in FIG. 4, the lower surface 150U of the source/drain pattern 150 may be positioned closer to the second surface 100b of the insulating layer 100 than the lower surface of the lowermost sub-gate structure S_GS. In other words, the length in the third direction D3 from the second surface 100b of the insulating layer 100 to the lower surface 150U of the source/drain pattern 150 may be smaller than the length in the third direction D3 from the second surface 100b of the insulating layer 100 to the lower surface of the lowermost sub-gate structure S_GS.

Further, the lower surface 150U of the source/drain pattern 150 may be positioned at a level lower than the lower surface 210U of the first portion 210 of the insulating pattern 200. For example, as shown in FIG. 4, the lower surface 150U of the source/drain pattern 150 may be positioned closer to the second surface 100b of the insulating layer 100 than the lower surface 210U of the first portion 210. In other words, the length in the third direction D3 from the second surface 100b of the insulating layer 100 to the lower surface 150U of the source/drain pattern 150 may be smaller than the length in the third direction D3 from the second surface 100b of the insulating layer 100 to the lower surface 210U of the first portion 210.

The source/drain pattern 150 may be an epitaxial pattern formed by a selective epitaxial growth process using the active pattern AP as seeds. The channel patterns NS may be portions of the active pattern AP extending between the source/drain patterns 150. The source/drain patterns 150 may serve as the sources and drains of transistors using the channel patterns NS as channel regions.

The source/drain pattern 150 of the semiconductor device according to some embodiments may include first source/drain pattern 151 and second source/drain pattern 152.

The second source/drain pattern 152 may be formed along the inner walls and bottom surfaces of the source/drain recesses 150R. The second source/drain pattern 152 formed along the inner walls of the source/drain recesses 150R may directly contact the inner gate spacers 135 and the active pattern AP. The second source/drain pattern 152 formed along the bottom surfaces of the source/drain recesses 150R may be coupled to the dummy source/drain pattern 160 or the through-via 300. The second source/drain pattern 152 may include a first material which is a semiconductor material. For example, the second source/drain pattern 152 may include silicon (Si) or germanium (Ge) which is a semiconductor material.

The first source/drain pattern 151 may be positioned on the second source/drain pattern 152. The second source/drain patterns 152 may be formed in at least a portion of the source/drain recesses 150R, and the remaining portions of the source/drain recesses may be filled with the first source/drain pattern 151. The first source/drain pattern 151 may include a semiconductor material.

The first source/drain pattern 151 may include the first material and a second material different from the first material. The second material may include, for example, carbon (C), silicon (Si), germanium (Ge), or tin (Sn). As an example, the second source/drain pattern 152 may include silicon (Si), and the first source/drain pattern 151 may include silicon germanium (SiGe).

However, the present disclosure is not limited thereto, and as another example, the first source/drain pattern 151 may include the same material as that in the second source/drain pattern 152. In this case, the concentrations of the constituent material in the first source/drain pattern 151 and the second source/drain pattern 152 may be different. For example, when the first source/drain pattern 151 and the second source/drain pattern 152 include silicon germanium (SiGe), the concentration of germanium (Ge) in the first source/drain pattern 151 may be greater than the concentration of germanium (Ge) in the second source/drain pattern 152; however, the present disclosure is not limited thereto. As yet another example, the first source/drain pattern 151 and the second source/drain pattern 152 may include the same material, and the first source/drain pattern 151 and the second source/drain pattern 152 may have the same concentration of the constituent material.

According to some embodiments, it has been described that each source/drain pattern 150 includes multiple layers; however, each source/drain pattern 150 is not limited thereto, and may include a single layer including a semiconductor material.

The dummy source/drain pattern 160 may be positioned on the insulating layer 100. The dummy source/drain pattern 160 may be positioned between the insulating layer 100 and the source/drain pattern 150. The dummy source/drain pattern 160 may be coupled to the source/drain pattern 150.

The dummy source/drain pattern 160 may be positioned in dummy source/drain recesses 160R extending in the third direction D3. The dummy source/drain recesses 160R may be filled with the dummy source/drain pattern 160. The lower surface and side surface of the dummy source/drain pattern 160 may be defined by the fourth portion 240 of the insulating pattern 200.

According to some embodiments, the plurality of dummy source/drain pattern 160 may be provided. In this case, the lengths of the dummy source/drain patterns 160 in the third direction D3 may be different. Specifically, as the width of each of the dummy source/drain pattern 160 in the first direction D1 increases, the length of the corresponding dummy source/drain pattern 160 in the third direction D3 may increase. Accordingly, a distribution of the lengths of the dummy source/drain pattern 160 in the third direction D3 may occur.

According to some embodiments, the dummy source/drain pattern 160 may be surrounded by the fourth portion 240 of the insulating pattern 200. The lower surface and side surface of the dummy source/drain pattern 160 may be completely covered by the fourth portion 240 of the insulating pattern 200. The dummy source/drain pattern 160 may contact the fourth portion 240 of the insulating pattern 200. Accordingly, the dummy source/drain pattern 160 may be positioned apart from the insulating layer 100.

According to some embodiments, the upper surface of the dummy source/drain pattern 160 may be positioned at a level lower than the lower surface 210U of the first portion 210 of the insulating pattern 200. For example, as shown in FIG. 4, the upper surface of the dummy source/drain pattern 160 may be positioned closer to the second surface 100b of the insulating layer 100 than the lower surface 210U of the first portion 210. In other words, the length in the third direction D3 from the second surface 100b of the insulating layer 100 to the upper surface of the dummy source/drain pattern 160 may be smaller than the length in the third direction D3 from the second surface 100b of the insulating layer 100 to the lower surface 210U of the first portion 210.

Accordingly, the upper surface of the dummy source/drain pattern 160 may be positioned closer to the second surface 100b of the insulating layer 100 than the lower surface of the lowermost sub-gate structure S_GS. In other words, the length in the third direction D3 from the second surface 100b of the insulating layer 100 to the upper surface of the dummy source/drain pattern 160 may be smaller than the length in the third direction D3 from the second surface 100b of the insulating layer 100 to the lower surface of the lowermost sub-gate structure S_GS.

The dummy source/drain pattern 160 may include the same material in the source/drain pattern 150. For example, the dummy source/drain pattern 160 may include a first material and a second material. The second material may be a material different from the first material. The second material may include, for example, carbon (C), silicon (Si), germanium (Ge), or tin (Sn).

In this case, the concentration of the second material in the dummy source/drain pattern 160 may be lower than the concentration of the second material that is included in the first source/drain pattern 151. As an example, when the first material includes silicon (Si) and the second material includes germanium (Ge), the concentration of germanium (Ge) that is included in the dummy source/drain pattern 160 may be lower than the concentration of germanium (Ge) that is included in the first source/drain pattern 151. However, the present disclosure is not limited thereto, and the concentration of the second material in the dummy source/drain pattern 160 may be greater than the concentration of the second material that is included in the first source/drain pattern 151. Further, for example, when the second source/drain pattern 152 and the dummy source/drain pattern 160 include silicon germanium (SiGe), the concentration of germanium (Ge) in the dummy source/drain pattern 160 may be greater than the concentration of germanium (Ge) in the second source/drain pattern 152. In FIG. 2, it is shown that the dummy source/drain patterns 160 are positioned between the through-via 300; however, this is merely for ease of explanation, and the dummy source/drain patterns are not limited thereto.

The semiconductor device according to some embodiments may further include an interlayer insulating layer 190.

The interlayer insulating layer 190 may be positioned on the side surface of the gate spacers 140, the side surface of the capping layers 145, and the upper surface of the source/drain pattern 150. The interlayer insulating layer 190 may not cover the upper surface of the capping layers 145. Further, the element isolation trench STI may be filled with the interlayer insulating layer 190. For example, the interlayer insulating layer 190 may be positioned on the third portion 230 of the insulating pattern 200 positioned on the inner walls and bottom surfaces of the element isolation trench STI. Accordingly, the interlayer insulating layer 190 may be positioned apart from the insulating layer 100.

The interlayer insulating layer 190 may include, for example, at least one of silicon oxide (SiO₂), silicon nitride (SiN), silicon oxynitride (SiON), and low-dielectric constant materials. The low-dielectric constant materials may include, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SILK, amorphous fluorinated carbon, silica aerogels, silica xerogels, mesoporous silica, or combinations thereof, but are not limited thereto.

According to some embodiments, between the gate spacers 140 and the interlayer insulating layer 190 and between the source/drain pattern 150 and the interlayer insulating layer 190, etch stop films may be further positioned. The etch stop films may include a material having etch selectivity to the interlayer insulating layer 190. The etch stop films 185 may include, for example, at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and combinations thereof.

The semiconductor device according to some embodiments may further include an upper insulating layer 195.

The upper insulating layer 195 may be positioned on the upper surface of the capping layers 145 and the upper surface of the interlayer insulating layer 190. The upper insulating layer 195 may include the same material as that in the interlayer insulating layer 190. For example, the upper insulating layer 195 may include at least one of silicon oxide (SiO₂), silicon nitride (SiN), silicon oxynitride (SiON), and low-dielectric constant materials.

The semiconductor device according to some embodiments may further include contact electrodes CT.

The contact electrodes CT may be positioned on the source/drain pattern 150. The contact electrodes CT may pass through the interlayer insulating layer 190 and the upper insulating layer 195 and be electrically coupled to the source/drain pattern 150.

The lower surface of the contact electrodes CT may be positioned, for example, at a level similar to the level of the upper surface of the uppermost channel patterns of the plurality of channel patterns NS. However, the present disclosure is not limited thereto, and the lower surface of the contact electrodes CT may be higher or lower than the lower surface of the uppermost channel patterns of the plurality of channel patterns NS. Alternatively, the lower surface of the contact electrodes CT may be positioned between the lower surface of the lowermost channel patterns of the plurality of channel patterns NS and the lower surface of the uppermost channel patterns.

The contact electrodes CT may include, for example, at least one of metals, metal alloys, conductive metal nitrides, conductive metal carbides, conductive metal oxides, conductive metal carbonitrides, and two-dimensional (2D) materials.

According to some embodiments, between the source/drain pattern 150 and the contact electrodes CT, silicide films may be further positioned. The silicide films may surround portions of the contact electrodes CT indented in the source/drain pattern 150. The silicide films may include a metal-silicide. For example, the silicide films may include, for example, at least one of titanium-silicides, tantalum-silicides, tungsten-silicides, nickel-silicides, and cobalt-silicides.

The semiconductor device according to some embodiments may further include upper wiring structures 420.

The upper wiring structures 420 may be positioned on the upper insulating layer 195. The upper wiring structures 420 may include upper wiring lines 421 and an upper wiring insulating layer 422.

The upper wiring lines 421 may be positioned on the upper insulating layer 195. The upper wiring lines 421 may include a metal (for example, copper). The upper wiring lines 421 may be electrically coupled to the contact electrodes CT.

The upper wiring insulating layer 422 may be positioned on the upper insulating layer 195. The upper wiring insulating layer 422 may cover the upper wiring structures 420. In other words, the upper wiring insulating layers 422 may cover the upper wiring lines 421, and the upper wiring lines 421 may be positioned in the upper wiring insulating layer 422. The upper wiring insulating layer 422 may include, for example, at least one of silicon oxide (SiO₂), silicon nitride (SiN), silicon oxynitride (SiON), or a low-dielectric constant material.

The lower wiring structure 410 may be positioned on the second surface 100b of the insulating layer 100. The lower wiring structure 410 may be, for example, a power delivery network that supplies a voltage (for example, a power voltage, etc.) to the source/drain pattern 150.

The lower wiring structure 410 may include lower wiring lines 411 and a lower wiring insulating layer 412.

The lower wiring lines 411 may be positioned on the second surface 100b of the insulating layer 100. The lower wiring lines 411 may include a metal (for example, copper). The lower wiring lines 411 may be electrically coupled to the through-via 300.

The lower wiring insulating layer 412 may be positioned on the second surface 100b of the insulating layer 100. The lower wiring insulating layer 412 may cover the lower wiring structure 410. In other words, the lower wiring insulating layer 412 may cover the lower wiring lines 411, and the lower wiring lines 411 may be positioned in the lower wiring insulating layer 412. The lower wiring insulating layer 412 may include, for example, at least one of silicon oxide (SiO₂), silicon nitride (SiN), silicon oxynitride (SiON), or a low-dielectric constant material.

The through-vias 300 may be positioned between the source/drain patterns 150 and the lower wiring structure 410. Each through-via 300 may be coupled to one source/drain pattern 150. For example, the through-vias 300 may be electrically coupled to source/drain patterns 150 that are not coupled to the contact electrodes CT. However, the through-vias 300 are not limited thereto, and may be electrically coupled to source/drain patterns 150 coupled to the contact electrodes CT.

Reference herein will be made to a single through-via

The through-via 300 may extend in the third direction D3 from the source/drain pattern 150 to the lower wiring structure 410. The upper surface of the through-via 300 may be coupled to the source/drain pattern 150. According to some embodiments, the source/drain pattern 150 and the lower wiring structure 410 may be electrically coupled to each other through the through-via 300. In other words, a voltage (for example, a power voltage, etc.) may be applied from the lower wiring structure 410 to the source/drain pattern 150 through the through-via 300.

Referring to FIG. 4 together, the through-via 300 of the semiconductor device according to some embodiments may include first via portion 310 that is surrounded by the second portion 220 of the insulating pattern 200, and second via portion 320 that is positioned between the first via portion 310 and the lower wiring structure 410. The first via portion 310 may refer to a portion of the through-via 300 surrounded by the second portion 220 of the insulating pattern 200.

The first via portion 310 may extend in the third direction D3 from the lower surface 150U of the source/drain pattern 150. The first via portion 310 may be vertically below the source/drain pattern 150 in the third direction D3. The first via portion 310 may be electrically coupled to the second via portion 320.

The first via portion 310 may be surrounded by at least a portion of the insulating pattern 200. For example, the first via portion 310 may be surrounded by the second portion 220 of the insulating pattern 200. In other words, the first via portion 310 may extend over the second portion 220 in a horizontal direction (for example, the first direction D1 and/or the second direction D2). The first via portion 310 may abut the second portion 220. The first via portion 310 may be positioned apart from the insulating layer 100 by the second portion 220.

According to some embodiments, the first width W1 of the first via portion 310 in the first direction D1 may decrease from the first surface 100a of the insulating layer 100. This may be due to the characteristics of the process of forming the first via portion 310 in the spaces formed by the removal of the dummy source/drain pattern 160. However, the present disclosure is not limited thereto, and for example, the first via portion 310 may further include portions in which the first width W1 of each first via portion in the first direction D1 increases from the first surface 100a of the insulating layer 100. In other words, the width of the first via portion 310 in the first direction D1 may increase and then decrease from the first surface 100a of the insulating layer 100. As another example, the first width W1 of the first via portion 310 in the first direction D1 may be constant.

According to some embodiments, as shown in FIG. 2, a plurality of first via portions 310 may be provided, and may be positioned on the lower surface of the source/drain pattern 150. In this case, the plurality of first via portions 310 may have different shapes. For example, as shown in FIG. 2, in a cross-section taken along the first direction D1 and the third direction D3, the side surface of the plurality of first via portions 310 may include different curved surfaces. As an example, the side surface of one of the plurality of first via portions 310 may have a curvature different from that of the side surface of another one of the plurality of first via portions 310. Alternatively, the minimum width in the first direction D1 of one of the plurality of first via portions 310 may be different from the minimum width in the first direction D1 of another one of the plurality of first via portions 310. For example, the width in the first direction D1 of an end portion on one side of one of the plurality of first via portions 310 may be different from the width in the first direction D1 of an end portion on one side of another one of the plurality of first via portions 310.

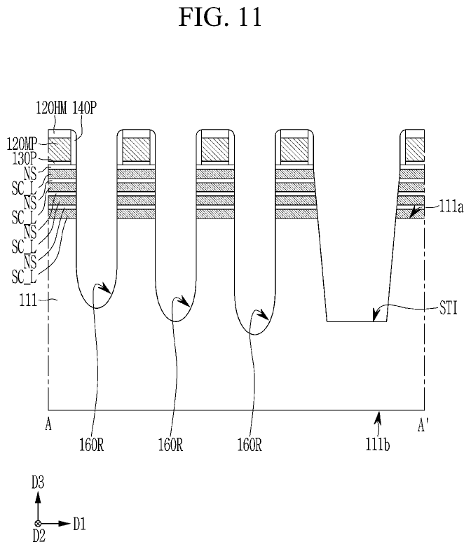

This is because, in the process of forming the dummy source/drain pattern 160 of the semiconductor device according to some embodiments, the lengths of the dummy source/drain recesses 160R (FIG. 11) in the third direction D3 may be different. For example, as the width of each dummy source/drain recess 160R in the first direction D1 increases, the length of the corresponding dummy source/drain recess 160R in the third direction D3 may increase. In other words, a distribution of the lengths in the third direction D3 of the dummy source/drain recesses 160R according to some embodiments may occur, and accordingly, in a cross-section taken along the first direction D1 and the third direction D3, the side surface shapes of the dummy source/drain recesses 160R may be different.

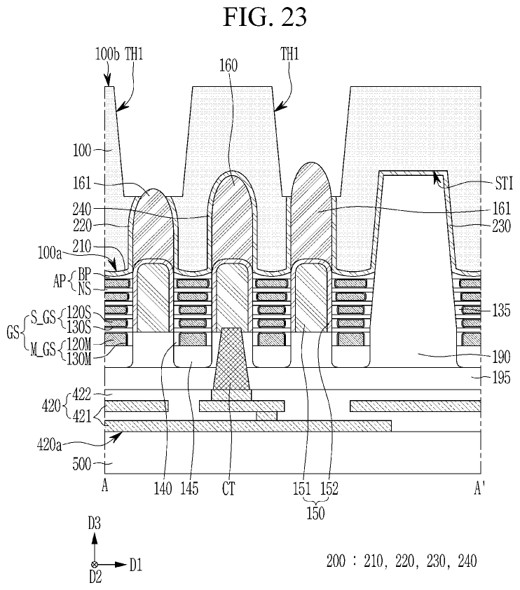

In this case, a method of manufacturing the semiconductor device according to some embodiments may form first through-holes TH1 (FIG. 23) through a dry etching process even when there is a distribution of the lengths of the dummy source/drain pattern 160, thereby easily exposing the dummy source/drain pattern 160 filled in the dummy source/drain recesses 160R. Then, the method may form the first via portion 310 in the spaces formed by the removal of the dummy source/drain pattern 160. Accordingly, the side surface shapes of the plurality of first via portions 310 may be different. This will be described below in detail.

The first via portion 310 may include the same material as that in the contact electrodes CT. The first via portion 310 may include, for example, at least one of metals, metal alloys, conductive metal nitrides, conductive metal carbides, conductive metal oxides, and conductive metal carbonitrides. However, the first via portion 310 are not limited thereto, and may include a material different from that in the contact electrodes CT.

The second via portion 320 may be positioned between the first via portion 310 and the lower wiring structure 410. The second via portion 320 may extend in the third direction D3 from the lower surface of the first via portion 310 toward the second surface 100b of the insulating layer 100. In other words, the second via portion 320 may extend in the third direction D3 and directly contact the lower surface of the first via portion 310. The second via portion 320 may be vertically below the first via portion 310 in the third direction D3. The second via portion 320 may pass through the insulating layer 100 and contact the lower wiring structure 410. The second via portion 320 may be electrically coupled to the lower wiring lines 411 of the lower wiring structure 410.

According to some embodiments, at a portion in which a second via portion 320 and a first via portion 310 abut each other, a curved portion may be provided. Accordingly, the second width W2 of the second via portion 320 in the first direction D1 may be larger than the first width W1 of the first via portion 310 in the first direction D1. For example, the width in the first direction D1 of the upper surface of the second via portion 320 may be larger than the maximum width of the first via portion 310 in the first direction D1. This may be due to the characteristics of the process of first forming the first through-holes TH1 such that some portions of the insulating pattern 200 are exposed, etching the exposed portions of the insulating pattern 200 to remove the dummy source/drain pattern 160, forming the first via portion 310 in the spaces formed by the removal of the dummy source/drain pattern 160, and forming the second via portion 320 in the first through-holes TH1 during the process of forming the second via portion 320. This will be described below in detail.

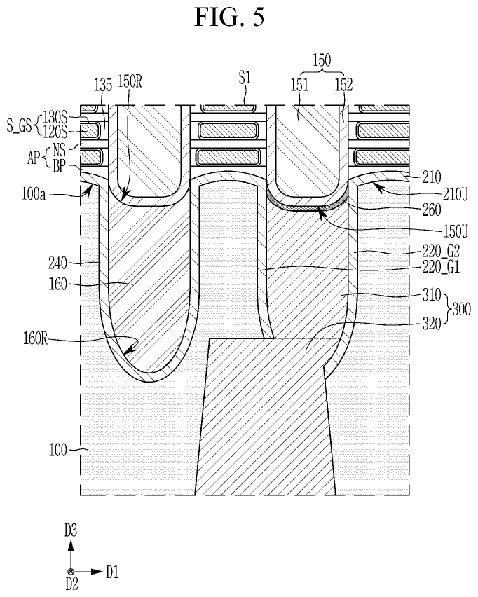

Accordingly, the upper surface of the second via portion 320 may contact the first via portion 310, the second portion 220 of the insulating pattern 200, and the insulating layer 100. The side surface of the second via portion 320 may contact the insulating layer 100. The second via portion 320 may not extend over the second portion 220 of the insulating pattern 200 in a horizontal direction (for example, the first direction D1 and/or the second direction D2). In other words, the side surface of the second via portion 320 may not contact the insulating pattern 200. However, the present disclosure is not limited thereto, at least a portion of the side surface of the second via portion 320 may contact the second portion 220 of the insulating pattern 200. This will be described below with reference to FIG. 5.

The second via portion 320 may include the same material as that in the first via portion 310. The second via portion 320 may include, for example, at least one of metals, metal alloys, conductive metal nitrides, conductive metal carbides, conductive metal oxides, and conductive metal carbonitrides. In this case, the second via portion 320 may be formed integrally with the first via portion 310 without any interfaces. However, the second via portion 320 is not limited thereto, and may include a material different from that in the first via portion 310.

The semiconductor device according to some embodiments may further include a silicide layer 260.

The silicide layer 260 may be positioned between the source/drain pattern 150 and the first via portion 310. The silicide layer 260 may be positioned along the boundaries of the first via portion 310 to abut the source/drain pattern 150. The silicide layer 260 may contact the second portion 220 of the insulating pattern 200, but is not limited thereto. The silicide layer 260 may include a metal-silicide. For example, the silicide layer 260 may include, for example, at least one of titanium-silicides, tantalum-silicides, tungsten-silicides, nickel-silicides, and cobalt-silicides. In some embodiments, between the silicide layer 260 and the through-via 300, barrier metal layers may be further positioned, but the present disclosure is not limited thereto.

Hereinafter, the insulating pattern 200 according to some embodiments will be described in detail with reference to FIG. 2 and FIG. 4.

Referring to FIG. 2 and FIG. 4, the insulating pattern 200 of the semiconductor device according to some embodiments may include the first portion 210 that is positioned between the lower pattern BP and the insulating layer 100, the second portion 220 that surrounds at least a portion of the through-via 300, the third portion 230 that is positioned on the inner walls and bottom surfaces of the element isolation trench STI, and the fourth portion 240 that surround the dummy source/drain pattern 160.

The first portion 210 of the insulating pattern 200 may be positioned on the first surface 100a of the insulating layer 100. The first portion 210 may be positioned between the first surface 100a of the insulating layer 100 and the lower surface of the lower pattern BP. Accordingly, the first portion 210 may be positioned between the sub-gate structure S_GS and the insulating layer 100. For example, the first portion 210 may be positioned between the lowermost sub-gate structure S_GS and the insulating layer 100. The first portion 210 may be vertically below the sub-gate structure S_GS in the third direction D3. The first portion 210 may be positioned on the first surface 100a of the insulating layer 100 to conform to it.

According to some embodiments, the lower surface 210U of the first portion 210 may be positioned at a level higher than that of the lower surface 150U of the source/drain pattern 150. In other words, the lower surface 210U of the first portion 210 may be positioned farther from the second surface 100b of the insulating layer 100 than the lower surface 150U of the source/drain pattern 150. In other words, the lower surface 210U of the first portion 210 may be positioned farther from the second surface 100b of the insulating layer 100 than the upper surface of the through-via 300. Accordingly, the lower patterns BP positioned on the first portion 210 and the through-via 300 are spaced apart from each other, and the lower pattern BP and the through-via 300 may be electrically insulated from each other.

The second portion 220 of the insulating pattern 200 may extend in the third direction D3. The second portion 220 may surround at least a portion of the through-via 300. For example, the second portion 220 may surround the first via portion 310 of the through-via 300. The second portion 220 may be positioned between the insulating layer 100 and the first via portion 310 of the through-via 300. In other words, the second portion 220 may conformally cover the first via portion 310 of the through-via 300 in a horizontal direction (for example, the first direction D1 and/or the second direction D2).

According to some embodiments, the second portion 220 may be positioned on the second via portion 320 of the through-via 300. The second portion 220 may be positioned on the upper surface of the second via portion 320 of the through-via 300. The lower surface of the second portion 220 may contact the upper surface of the second via portion 320 of the through-via 300. Accordingly, the second portion 220 may extend under at least a portion of the through-via 300 in a horizontal direction (for example, the first direction D1 and/or the second direction D2). For example, the second portion 220 may extend under the first via portion 310 in a horizontal direction (for example, the first direction D1 and/or the second direction D2). Further, the second portion 220 may not extend over or under the second via portion 320 in a horizontal direction (for example, the first direction D1 and/or the second direction D2).

In an embodiment, the second portion 220 may extend in the third direction D3 and cover at least a portion of the side surface of the source/drain pattern 150. The second portion 220 may surround at least a portion of the side surface of the source/drain pattern 150. Accordingly, the source/drain pattern 150 may be positioned apart from the insulating layer 100 by the second portion 220.

The second portion 220 may cover the side surface of the first via portion 310 and at least a portion of the side surface of the source/drain pattern 150. Further, the lower surface of the first portion 210 may be positioned at a level higher than that of the upper surface of the through-via 300. Accordingly, between the lower pattern BP and the through-via 300 and/or between the sub-gate structure S_GS positioned on the first portion 210 and the through-via 300, the first portion 210 and the second portion 220 may be positioned. In other words, the lower pattern BP and the through-via 300 may be spaced apart from each other, and/or the sub-gate structure S_GS and the through-via 300 may be spaced apart from each other. Accordingly, the lower pattern BP and the through-via 300 and/or the sub-gate structure S_GS and the through-via 300 may be electrically insulated from each other by the first portion 210 and the second portion 220.

According to some embodiments, the width in the first direction D1 between the outer surfaces of each second portion 220 may decrease from the first surface 100a of the insulating layer 100. This may be due to the characteristics of the process of forming the dummy source/drain pattern 160 and then forming the second portion 220 along the outer surfaces of the dummy source/drain pattern 160. However, the present disclosure is not limited thereto, and the second portion 220 may further include sections in which the width in the first direction D1 between the outer surfaces of each second portion 220 increases from the first surface 100a of the insulating layer 100. In other words, the width in the first direction D1 between the outer surfaces of each second portion 220 may increase and then decrease from the first surface 100a of the insulating layer 100.

According to some embodiments, a plurality of second portions 220 may be provided, and be positioned on the side surfaces of the first via portions 310, respectively. In this case, the plurality of second portions 220 may have different shapes. For example, in a cross-section taken along the first direction D1 and the third direction D3, the side surface of the plurality of second portions 220 may include different curved surfaces. As an example, the side surface of one of the plurality of second portions 220 may have a curvature different from that of the side surface of another one of the plurality of second portions 220. Alternatively, the minimum distance between a second portion 220 covering both side surfaces of one first via portion 310 may be different from the minimum distance between a second portion 220 covering both side surfaces of another first via portion 310.

This is because, in the process of forming the dummy source/drain pattern 160 of the semiconductor device according to some embodiments, the lengths of the dummy source/drain recesses 160R in the third direction D3 may be different. For example, as the width of each dummy source/drain recess 160R in the first direction D1 increases, the length of the corresponding dummy source/drain recess 160R in the third direction D3 may increase. In other words, a distribution of the lengths in the third direction D3 of the dummy source/drain recesses 160R according to some embodiments may occur, and accordingly, in a cross-section taken along the first direction D1 and the third direction D3, the side surface shapes of the dummy source/drain recesses 160R may be different. Accordingly, since the second portion 220 is formed along the outer surfaces of the dummy source/drain pattern 160, the shape of the side surface of the second portion 220 may be different.

The method of manufacturing the semiconductor device according to some embodiments may form first through-holes TH1 through a dry etching process even when there is a distribution of the lengths of the dummy source/drain pattern 160, thereby easily exposing the second portion 220. This will be described below in detail.

As shown in FIG. 2, the third portion 230 of the insulating pattern 200 may be positioned in the element isolation trench STI. Specifically, the third portion 230 may be positioned on the inner walls and bottom surfaces of the element isolation trench STI. The third portion 230 may be positioned along the inner walls and bottom surfaces of the element isolation trench STI so as to conform to them. The third portion 230 may be positioned between the insulating layer 100 and the interlayer insulating layer 190. The third portion 230 may contact the insulating layer 100 and the interlayer insulating layer 190.

According to some embodiments, the first height H1 of the third portion 230 in the third direction D3 may be greater than the second height H2 of the second portion 220 in the third direction D3. In this case, the upper surface of the third portion 230 may be positioned substantially at the same level as that of the upper surface of the second portion 220. Accordingly, the lower surface of the third portion 230 may be positioned at a level lower than the lower surface of the second portion 220. In other words, the lower surface of the third portion 230 may be positioned closer to the second surface 100b of the insulating layer 100 than the lower surface of the second portion 220 are.

In this case, the first height H1 of the third portion 230 in the third direction D3 may be substantially the same as the length of the inner walls of the element isolation trench STI in the third direction D3. In other words, according to some embodiments, the second height H2 of the second portion 220 in the third direction D3 may be smaller than the height of the inner walls of the element isolation trench STI in the third direction D3. This may be due to the characteristics of the process of forming the first through-holes TH1 such that the second portion 220 of the insulating pattern 200 is exposed and etching the exposed second portion 220 when the through-via 300 is formed by etching at least a portion of the insulating pattern 200 according to some embodiments.

The fourth portion 240 of the insulating pattern 200 may extend in the third direction D3. The fourth portion 240 may surround the dummy source/drain pattern 160. For example, the fourth portion 240 may surround the lower surface and side surface of the dummy source/drain pattern 160. The fourth portion 240 may be positioned between the insulating layer 100 and the dummy source/drain pattern 160. In other words, the fourth portion 240 may extend under the dummy source/drain pattern 160 in the first direction D1 and/or the second direction D2.

According to some embodiments, the fourth portion 240 may extend in the third direction D3 and cover at least a portion of the side surface of the source/drain pattern 150. The fourth portion 240 may surround at least a portion of the side surface of the source/drain pattern 150. Accordingly, the source/drain pattern 150 may be positioned apart from the insulating layer 100 by the fourth portion 240.

According to some embodiments, the height of the fourth portion 240 in the third direction D3 may be greater than the second height H2 of the second portion 220 in the third direction D3, but is not limited thereto. For example, the height of the fourth portion 240 in the third direction D3 may be smaller than or equal to the second height H2 of the second portion 220 in the third direction D3. This is because a distribution of the heights of the dummy source/drain pattern 160 in the third direction D3 is caused by the process of forming the dummy source/drain recesses 160R.

In the semiconductor device according to some embodiments, the insulating pattern 200 may be positioned on the first surface 100a of the insulating layer 100. Specifically, the second portion 220 of the insulating pattern 200 may surround at least a portion of the through-via 300. Accordingly, during the process of forming the through-via 300, etching of the surrounding material layers adjacent to the through-via 300 (for example, the insulating layer 100, the lower pattern BP, and/or the sub-gate structure S_GS) may be prevented, and a problem of a short circuit between the through-via 300 and the surrounding material layers may be prevented. Therefore, the reliability of the semiconductor device may be improved.

Further, in the semiconductor device according to some embodiments, the first portion 210 of the insulating pattern 200 may be positioned between the insulating layer 100 and the lower pattern BP, and the second portion 220 of the insulating pattern 200 may cover the side surface of the first via portion 310 and at least a portion of the side surface of the source/drain pattern 150. Accordingly, even when the through-via 300 is formed, the lower pattern BP and the through-via 300 and/or the sub-gate structure S_GS and the through-via 300 may be electrically insulated from each other by the first portion 210 and the second portion 220. Therefore, the reliability of the semiconductor device may be improved.

Furthermore, the method of manufacturing the semiconductor device according to some embodiments may form first through-holes TH1 through a dry etching process even when there is a distribution of the lengths of the dummy source/drain pattern 160, thereby easily exposing the dummy source/drain pattern 160 filled in the dummy source/drain recesses 160R.

Hereinafter, semiconductor devices according to some embodiments will be described with reference to FIG. 5 to FIG. 9.

FIGS. 5 to 8 are cross-sectional views of portions of semiconductor devices corresponding to the S1 region in FIG. 2 according to one or more example embodiments.

FIG. 5 is a cross-sectional view of a portion of a semiconductor device according to some embodiments which corresponds to the S1 region in FIG. 2.

FIG. 5 includes features similar to those described above, and repeated descriptions may be omitted. In some embodiments, the shape of second portion 220 of insulating pattern 200 may be different from that described above.

The semiconductor device according to some embodiments may include an insulating layer 100, an insulating pattern 200, an active pattern AP, a field insulating layer 105, a gate structure GS, a source/drain pattern 150, a dummy source/drain pattern 160, a lower wiring structure 410, and a through-via 300. The insulating pattern 200 may include first to fourth portions 210 to 240.

As described above, the second portion 220 of the insulating pattern 200 may extend under the first via portion 310 in a horizontal direction (for example, the first direction D1 and/or the second direction D2), and the second portion 220 of the insulating pattern 200 may not extend under or over the second via portion 320 in a horizontal direction (for example, the first direction D1 and/or the second direction D2).

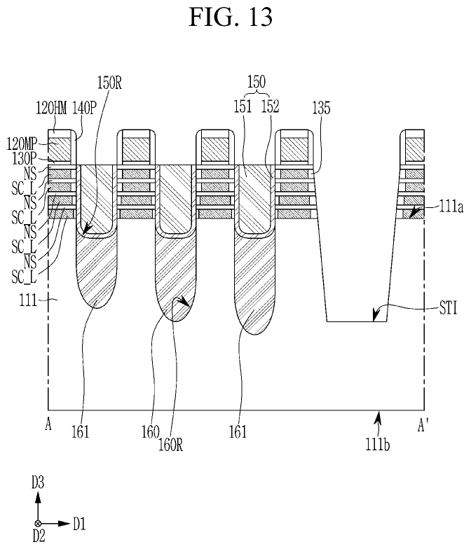

Referring to FIG. 5, the central axis of the first via portion 310 according to some embodiments may be spaced apart from the central axis of the second via portion 320. For example, as shown in FIG. 5, the central axis of the first via portion 310 along the third direction D3 may be substantially the same as the central axis of the source/drain pattern 150 along the third direction D3. Further, the central axis of the first via portion 310 along the third direction D3 may be spaced apart from the central axis of the second via portion 320 along the third direction D3, in the first direction D1. In other words, the second via portion 320 may be misaligned with the first via portion 310. This may be due to the process characteristic in which, in the process of forming the second via portion 320, when first through-holes TH1 to expose dummy patterns 161 (FIG. 13) are formed by a dry etching process, misalignment occurs.

In FIG. 5, it is shown that in the first direction D1, the central axis of the first via portion 310 along the third direction D3 is spaced apart from the central axis of the second via portion 320 along the third direction D3; however, the present disclosure is not limited thereto. For example, the central axis of the first via portion 310 along the third direction D3 may be spaced apart from the central axis of the second via portion 320 along the third direction D3, in the first direction D1 and/or the second direction D2.

According to some embodiments, a first portion 220_G1 of the second portion 220 of the insulating pattern 200 may be positioned on the upper surface of the second via portion 320. A second portion 220_G2 of the second portion 220 of the insulating pattern 200 may be positioned on the side surface of the second via portion 320. In other words, the second portion 220_G2 of the second portion 220 may extend to the second via portion 320 in a horizontal direction (for example, the first direction D1 and/or the second direction D2). As an example, the length by which a second portion 220 extends to a second via portion 320 in the horizontal direction may be smaller than the length of the second via portion 320 along the third direction D3. Accordingly, the side surface of the second via portion 320 may contact the insulating layer 100, the first via portion 310, and the second portion 220.

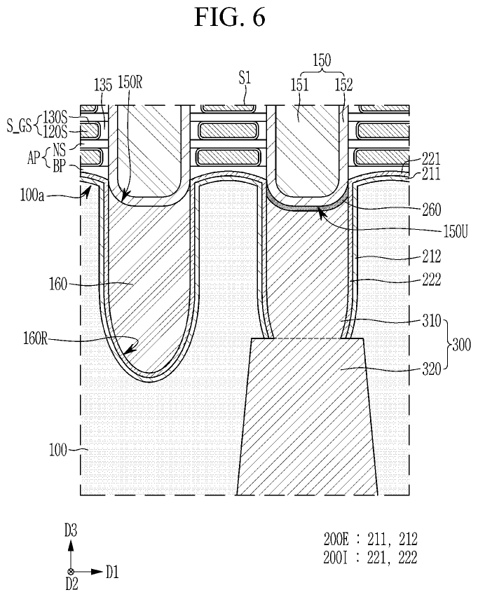

FIG. 6 is a cross-sectional view of a portion of a semiconductor device according to some embodiments which corresponds to the S1 region in FIG. 2.

FIG. 6 includes features similar to those described above, and repeated descriptions may be omitted. In FIG. 6, each insulating pattern 200 may include multiple layers, and will be described below.

The semiconductor device according to some embodiments may include an insulating layer 100, an insulating pattern 200, an active pattern AP, a field insulating layer 105, a gate structure GS, a source/drain pattern 150, a dummy source/drain pattern 160, a lower wiring structure 410, and a through-via 300. The insulating pattern 200 may include first to fourth portions 210 to 240.

As described above, the insulating pattern 200 includes the first to fourth portions 210 to 240. Each insulating pattern 200 may include a single layer.

Referring to FIG. 6, according to some embodiments, each insulating pattern 200 may include multiple layers. For example, the insulating pattern 200 may include an outer insulating pattern 200E and an inner insulating pattern 2201.

The outer insulating pattern 200E may be positioned on the first surface 100a of the insulating layer 100. The outer insulating pattern 200E may be positioned between the first surface 100a of the insulating layer 100 and the lower pattern BP. Further, the outer insulating pattern 200E may surround at least a portion of the through-via 300. The outer insulating pattern 200E may be positioned between the insulating layer 100 and the through-via 300. Also, the outer insulating pattern 200E may surround the dummy source/drain pattern 160. The insulating pattern 200 may be positioned between the insulating layer 100 and the dummy source/drain pattern 160. Further, the outer insulating pattern 200E may be positioned in the element isolation trench STI of the insulating layer 100. In other words, the outer insulating pattern 200E may be positioned between the insulating layer 100 and the interlayer insulating layer 190.

Accordingly, the outer insulating pattern 200E may include first portion 211 that is positioned between the lower pattern BP and the insulating layer 100, and a second portion 212 that surrounds at least a portion of the through-via 300. In this case, the first and second portion 211 and 212 of each outer insulating pattern 200E may be integrally formed without any interface, but are not limited thereto. Furthermore, the outer insulating pattern 200E may further include portions that are positioned on the inner walls and bottom surfaces of the element isolation trench STI, and portions that surround the dummy source/drain pattern 160.

The outer insulating pattern 200E may include various insulating materials. The outer insulating pattern 200E may include a material having etch selectivity to the insulating layer 100. For example, the outer insulating pattern 200E may include at least one of silicon nitride (SiN), silicon oxynitride (SiON), silicon carbonitride (SiCN), silicon oxycarbide (SiOC), and silicon oxycarbonitride (SiOCN). Alternatively, the outer insulating pattern 200E may include a metal oxide or a metal nitride, such as aluminum oxide (Al₂O₃) or aluminum nitride (AlN).

The inner insulating pattern 2201 may be positioned on the outer insulating pattern 200E. The inner insulating pattern 2201 may be positioned on the outer insulating pattern 200E so as to conform to the pattern 200E. For example, a first portion 221 of the inner insulating pattern 2201 may be positioned on the first portion 211 of the outer insulating pattern 200E. In other words, the first portion 221 of the inner insulating pattern 2201 may be positioned between the first portion 211 of the outer insulating pattern 200E and the lower pattern BP. Further, a second portion 222 of the inner insulating pattern 2201 may be positioned on the second portion 212 of the outer insulating pattern 200E. The second portion 222 of the inner insulating pattern 2201 may be positioned between the second portion 212 of the outer insulating pattern 200E and the through-via 300.

The inner insulating pattern 2201 may include a material different from that in the outer insulating pattern 200E. The inner insulating pattern 2201 may include a material having etch selectivity to the outer insulating pattern 200E. For example, the inner insulating pattern 2201 may include at least one of silicon nitride (SiN), silicon oxynitride (SiON), silicon carbonitride (SiCN), silicon oxycarbide (SiOC), silicon oxycarbonitride (SiOCN), aluminum nitride (AlN), and aluminum oxide (Al₂O₃).

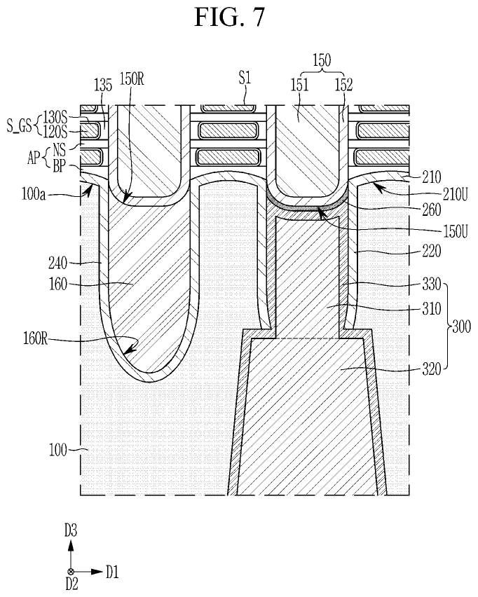

FIG. 7 is a cross-sectional view of a portion of a semiconductor device according to some embodiments which corresponds to the S1 region in FIG. 2.

FIG. 7 includes features similar to those described above, and repeated descriptions may be omitted. In FIG. 7, a barrier layer 330 is further included, and will be described below.

The semiconductor device according to some embodiments may include an insulating layer 100, an insulating pattern 200, an active pattern AP, a field insulating layer 105, a gate structure GS, a source/drain pattern 150, a dummy source/drain pattern 160, a lower wiring structure 410, and a through-via 300. The insulating pattern 200 may include first to fourth portions 210 to 240.

As described above, the insulating pattern 200 may include the first to fourth portions 210 to 240. Each insulating pattern 200 may include a single layer.

Referring to FIG. 7, the semiconductor device according to some embodiments may further include the barrier layer 330 that is positioned between the through-via 300 and the second portion 220 of the insulating pattern 200.

The barrier layer 330 may surround the through-via 300. The barrier layer 330 may extend in the third direction D3 and cover the side surface of the through-via 300. The barrier layer 330 may be positioned between the through-via 300 and the silicide layer 260, but is not limited thereto. The barrier layer 330 may be positioned between the through-via 300 and the second portion 220 of the insulating pattern 200 and between the through-via 300 and the insulating layer 100. The barrier layer 330 may include a conductive material. For example, the barrier layer 330 may include, for example, at least one of metals, metal alloys, conductive metal nitrides, conductive metal carbides, conductive metal oxides, and conductive metal carbonitrides.

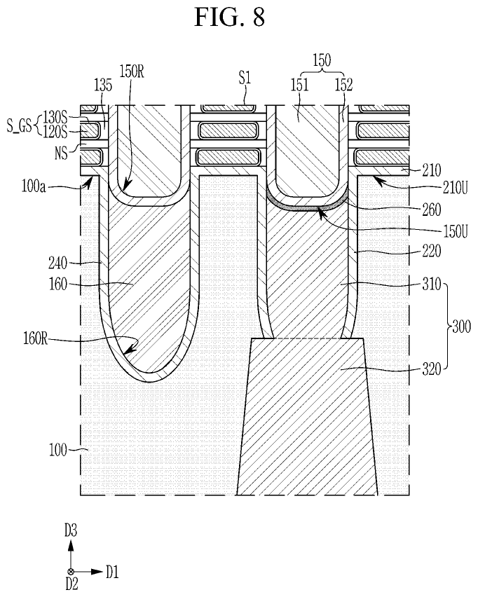

FIG. 8 is a cross-sectional view of a portion of a semiconductor device according to some embodiments which corresponds to the S1 region in FIG. 2.

FIG. 8 includes features similar to those described above, and repeated descriptions may be omitted. In FIG. 8, no lower patterns BP are provided, and will be described below.

The semiconductor device according to some embodiments may include an insulating layer 100, an insulating pattern 200, an active pattern AP, a field insulating layer 105, a gate structure GS, a source/drain pattern 150, a dummy source/drain pattern 160, a lower wiring structure 410, and a through-via 300. The insulating pattern 200 may include first to fourth portions 210 to 240.

As described above, each active pattern AP may include a lower pattern BP and a plurality of channel patterns NS.

However, referring to FIG. 8, the semiconductor device according to some embodiments may include no lower pattern BP. In other words, the first portion 210 of the insulating pattern 200 may contact the gate structure GS. For example, the first portion 210 may contact the lowermost sub-gate structure S_GS. Also, the first portion 210 may contact the inner gate spacer 135. This may be because a substrate 111 positioned between the dummy source/drain pattern 160 adjacent to the first direction D1 has been completely removed in the process of removing the substrate 111.

However, even in this case, the lower surface 210U of the first portion 210 may be positioned at a level higher than that of the lower surface 150U of the source/drain pattern 150. In other words, the lower surface 210U of the first portion 210 may be positioned farther from the second surface 100b of the insulating layer 100 than the lower surface 150U of the source/drain pattern 150 are.

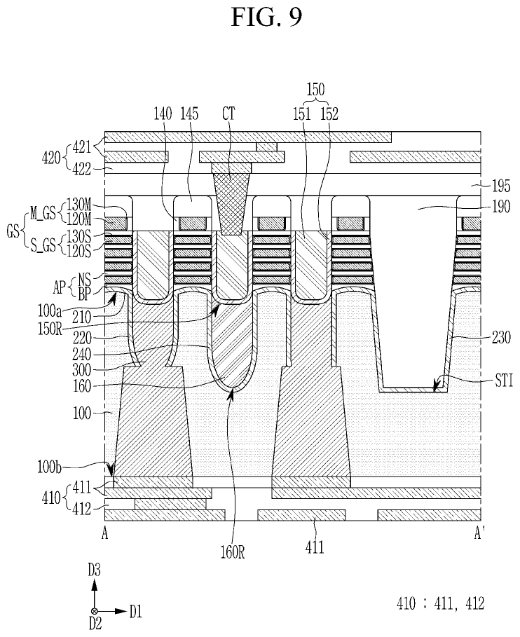

FIG. 9 is a cross-sectional view illustrating a semiconductor device according to one or more example embodiments.

FIG. 9 includes features similar to those described above, and repeated descriptions may be omitted. In FIG. 9, no inner gate spacers are provided, and will be described below.

The semiconductor device according to some embodiments may include an insulating layer 100, an insulating pattern 200, an active pattern AP, a field insulating layer 105, a gate structure GS, a source/drain pattern 150, a dummy source/drain pattern 160, a lower wiring structure 410, and a through-via 300. The insulating pattern 200 may include first to fourth portions 210 to 240.

As described above, the inner gate spacers may be positioned on the side surface of the sub-gate structure S_GS.

However, referring to FIG. 9, the semiconductor device according to some embodiments may include no inner gate spacers 135. Accordingly, the sub-gate structure S_GS may contact the source/drain pattern 150. In other words, the side surface of the source/drain pattern 150 may contact the side surface of the sub-gate structure S_GS.

Hereinafter, a method of manufacturing a semiconductor device according to an embodiment will be described with reference to FIG. 10 to FIG. 27.

FIGS. 10 to 27 are cross-sectional views illustrating a method of manufacturing a semiconductor device according to one or more example embodiments.

As shown in FIG. 10, on a substrate 111, an upper pattern structure U_AP is formed, and preliminary gate insulating layers 130P, preliminary main gate electrodes 120MP, and preliminary capping layers 120_HM are formed.

First, on the substrate 111, the upper pattern structure U_AP is formed. The substrate 111 may be a silicon-on-insulator (SOI) or bulk silicon. Alternatively, the substrate 111 may be a silicon substrate, or may include other materials such as silicon germanium (SiGe), silicon germanium on insulator (SGOI), indium antimonide, a lead tellurium compound, indium arsenide, indium phosphide, gallium arsenide, or gallium antimonide, but is not limited thereto.

The substrate 111 may have a first surface 111a and a second surface 111b. The first surface 111a and the second surface 111b of the substrate 111 may be formed as a plane parallel with a first direction D1 and a second direction D2 intersecting with the first direction D1. The first surface 111a of the substrate 111 may be the opposite to the second surface 111b in the third direction D3. The first surface 111a of the substrate 111 may be referred to as the upper surface or front side of the substrate 111. The second surface 111b of the substrate 111 may be referred to as the lower surface or back side of the substrate 111. In some embodiments, logic circuits in a cell area may be implemented on the first surface 111a of the substrate 111.

The upper pattern structure U_AP may be positioned on the first surface 111a of the substrate 111. The upper pattern structure U_AP may include sacrifice patterns SC_L and active patterns ACT_L alternately stacked on the substrate 111. For example, the sacrifice patterns SC_L may include silicon germanium (SiGe). The active patterns ACT_L may include silicon (Si).

Subsequently, at least a portion of the substrate 111 and the upper pattern structure U_AP may be etched to form element isolation trench STI. The element isolation trench STI may pass through the upper pattern structure U_AP. The element isolation trench STI may pass through at least a portion of the substrate 111.

Next, on the upper pattern structure U_AP, the preliminary gate insulating layers 130P, the preliminary main gate electrodes 120MP, and the preliminary capping layers 120_HM may be formed.

The preliminary gate insulating layers 130P may include, for example, silicon oxide (SiO₂), but are not limited thereto. The preliminary main gate electrodes 120MP may include, for example, polysilicon, but are not limited thereto. The preliminary capping layers 120_HM may include, for example, silicon nitride, but are not limited thereto.

On both side surfaces of each preliminary main gate electrode 120MP, preliminary gate spacers 140p may be formed.

As shown in FIG. 11, at least a portion of the upper pattern structure U_AP and the substrate 111 may be etched using the preliminary main gate electrodes 120MP and the preliminary gate spacers 140p as a mask, such that dummy source/drain recesses 160R are formed. The dummy source/drain recesses 160R may pass through the upper pattern structure U_AP. The dummy source/drain recesses 160R may pass through at least a portion of the substrate 111. In other words, at least a portion of the dummy source/drain recesses 160R may be formed in the substrate 111.

In this case, the heights of the dummy source/drain recesses 160R in the third direction D3 may be different. For example, as the width of each of the dummy source/drain recesses 160R in the first direction D1 increases, the height of the corresponding dummy source/drain recess 160R in the third direction D3 may increase. According to some embodiments, a distribution of the heights of the dummy source/drain recesses 160R in the third direction D3 may occur.

As the dummy source/drain recesses 160R are formed, the active pattern ACT_L may be divided, whereby the plurality of channel patterns NS may be formed. On both sides of each dummy source/drain recess 160R, a plurality of channel patterns NS may be positioned. Structures in which a plurality of channel patterns NS and sacrifice patterns SC_L are alternately stacked may be provided. In this case, the lengths of the plurality of channel patterns NS may be different or the same.

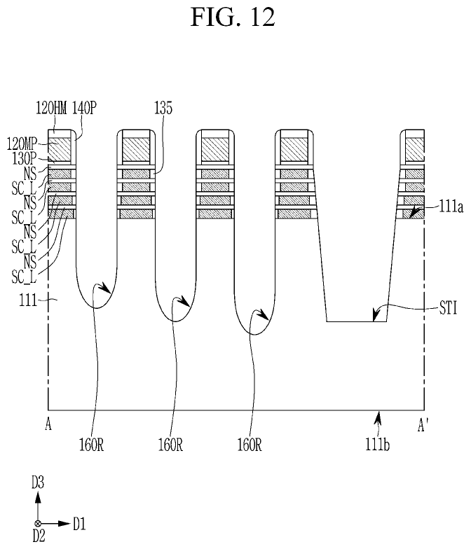

As shown in FIG. 12, at least a portion of the exposed side surface of the sacrifice patterns SC_L may be removed, and in the spaces formed by the removal, inner gate spacers 135 may be formed. The inner gate spacers 135 may be formed on the side surface of the sacrifice patterns SC_L. However, the present disclosure is not limited thereto, and according to some embodiments, the process of forming the inner gate spacers 135 may be omitted (e.g., FIG. 9).

As shown in FIG. 13, the dummy source/drain pattern 160 and the source/drain pattern 150 may be formed in the dummy source/drain recesses 160R.

First, the dummy source/drain pattern 160 may be formed in the dummy source/drain recesses 160R. The dummy source/drain pattern 160 may be formed on the substrate 111. The dummy source/drain pattern 160 may be formed using an epitaxial growth method. The dummy source/drain pattern 160 may directly contact the substrate 111. In this case, the upper surface of the dummy source/drain pattern 160 may be formed lower than the lower surface of the lowermost of the sacrifice patterns SC_L.

The dummy source/drain pattern 160 may include a first material and a second material. The second material may be a material different from the first material. The second material may include, for example, carbon (C), silicon (Si), germanium (Ge), or tin (Sn).

According to some embodiments, the dummy source/drain pattern 160 may include dummy patterns 161 that are removed in the subsequent process of forming the through-via 300. In other words, some of the dummy source/drain pattern 160 may be dummy patterns 161 for forming the through-via 300 (FIG. 2). In the subsequent process, the dummy patterns 161 may be removed, and the through-via 300 may be formed in the spaces formed by the removal. Hereinafter, for ease of explanation, the dummy source/drain pattern 160 that are removed in the process of forming the through-via 300 are referred to as the dummy patterns 161.

According to some embodiments, the heights of the dummy source/drain pattern 160 in the third direction D3 may be different. This is because the dummy source/drain pattern 160 are formed in the dummy source/drain recesses 160R having different heights in the third direction D3. Accordingly, a distribution of the heights of the dummy source/drain pattern 160 in the third direction D3 may occur.

Subsequently, the source/drain pattern 150 may be formed on the dummy source/drain pattern 160. The source/drain pattern 150 may be formed using an epitaxial growth method. Specifically, the second source/drain pattern 152 may be formed along the side walls and bottom surfaces of the source/drain recesses 150R. Next, the first source/drain pattern 151 may be formed on the second source/drain pattern 152.

The second source/drain pattern 152 may include a first material. The first material may include a semiconductor material. For example, the first material may include silicon (Si) or germanium (Ge) which is a semiconductor material.

The first source/drain pattern 151 may include the same material as that in the dummy source/drain pattern 160. The first source/drain pattern 151 may include the first material and the second material. The second material may include, for example, carbon (C), silicon (Si), germanium (Ge), or tin (Sn). As an example, the second source/drain pattern 152 may include silicon (Si), and the first source/drain pattern 151 may include silicon germanium (SiGe).

However, the present disclosure is not limited thereto, and as another example, the first source/drain pattern 151 may include the same material as that in the second source/drain pattern 152. In this case, the concentrations of the constituent material in the first source/drain pattern 151 and the second source/drain pattern 152 may be different. For example, when the first source/drain pattern 151 and the second source/drain pattern 152 include silicon germanium (SiGe), the concentration of germanium (Ge) in the first source/drain pattern 151 may be greater than the concentration of germanium (Ge) in the second source/drain pattern 152; however, the present disclosure is not limited thereto. As yet another example, the first source/drain pattern 151 and the second source/drain pattern 152 may include the same material, and the first source/drain pattern 151 and the second source/drain pattern 152 may have the same concentration of the constituent material.

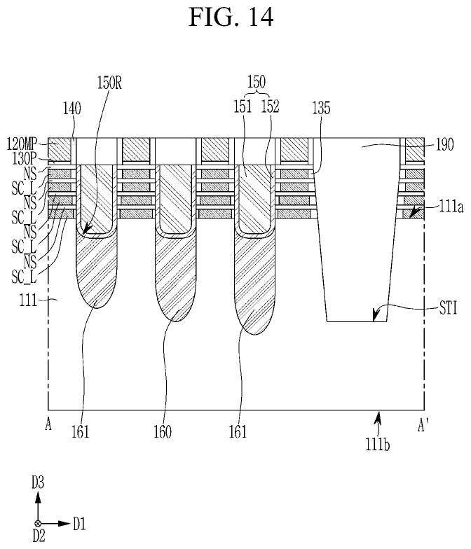

As shown in FIG. 14, the interlayer insulating layer 190 may be formed on the source/drain pattern 150. Also, the interlayer insulating layer 190 may be formed in the element isolation trench STI.

Subsequently, at least a portion of the interlayer insulating layer 190 and the preliminary capping layers 120_HM may be removed to expose the upper surface of the preliminary main gate electrodes 120MP. Some of the preliminary gate spacers 140P may be removed together such that gate spacers 140 are formed.

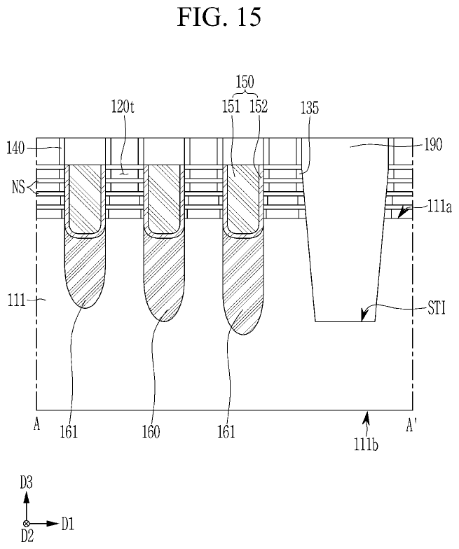

As shown in FIG. 15, the preliminary gate insulating layers 130P and the preliminary main gate electrodes 120MP may be removed to expose the portions of the upper pattern structure U_AP between the gate spacers 140. Subsequently, the sacrifice patterns SC_L may be removed to form gate trenches 120t between the plurality of channel patterns NS.

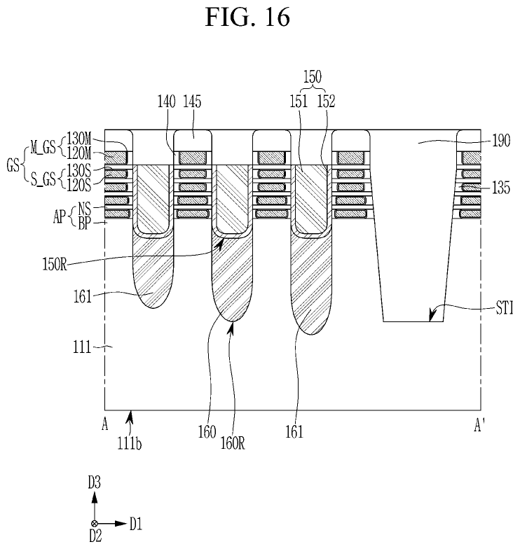

As shown in FIG. 16, the sub-gate insulating layers 130S and the sub-gate electrodes 120S may be sequentially formed in the gate trenches 120t. Also, the main gate insulating layers 130M, the main gate electrodes 120M, and the capping layers 145 may be sequentially formed.

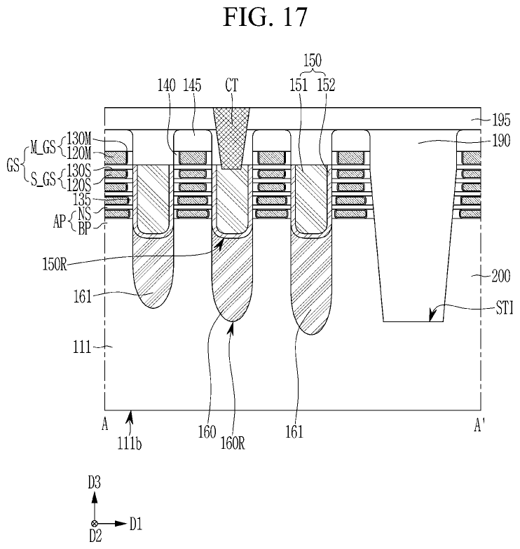

As shown in FIG. 17, the upper insulating layer 195 may be formed on the interlayer insulating layer 190, and the contact electrodes CT may be formed so as to pass through the upper insulating layer 195 and the interlayer insulating layer 190.

First, the upper insulating layer 195 may be formed so as to cover the upper surface of the interlayer insulating layer 190 and the upper surface of the capping layers 145. The upper insulating layer 195 may include the same material as that in the interlayer insulating layer 190. For example, the upper insulating layer 195 may include at least one of silicon oxide (SiO₂), silicon nitride (SiN), silicon oxynitride (SiON), and low-dielectric constant materials.

Subsequently, contact holes may be formed so as to pass through the upper insulating layer 195 and the interlayer insulating layer 190 and expose the source/drain pattern 150. Contact holes may not be formed above the source/drain pattern 150 positioned on the dummy patterns 161, but are not limited thereto.

Next, the contact holes may be filled, whereby the contact electrodes CT may be formed so as to be electrically coupled to the source/drain pattern 150. Accordingly, the contact electrodes CT may pass through the upper insulating layer 195 and the interlayer insulating layer 190 and be electrically coupled to the source/drain pattern 150.

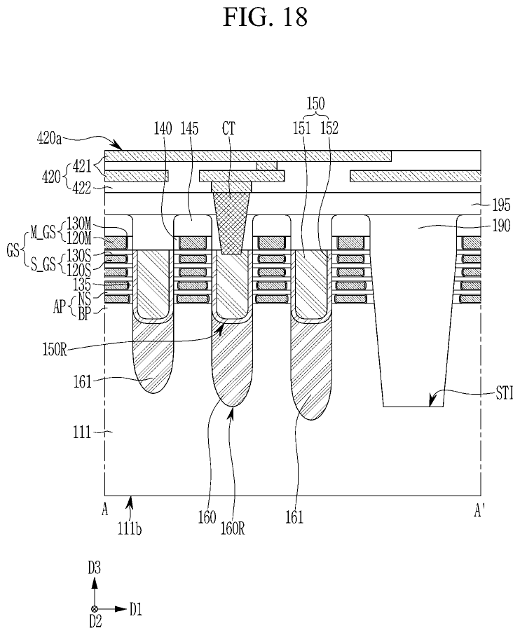

As shown in FIG. 18, the upper wiring structures 420 may be formed on the upper insulating layer 195. The upper wiring structures 420 may include upper wiring lines 421 and an upper wiring insulating layer 422. The upper wiring lines 421 may be formed on the upper insulating layer 195. The upper wiring lines 421 may include a metal (for example, copper). The upper wiring lines 421 may be electrically coupled to the contact electrodes CT.

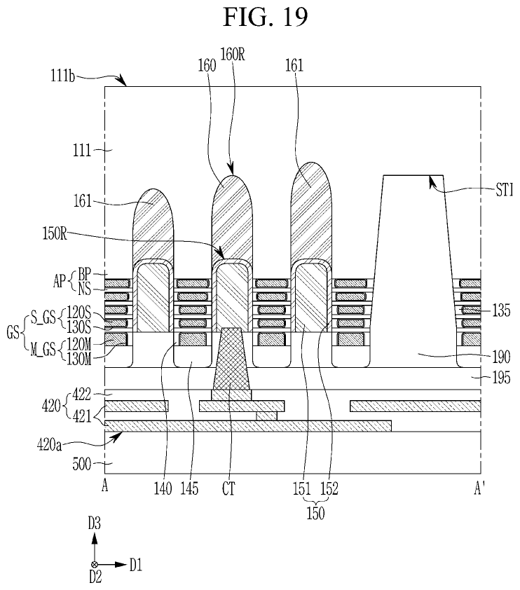

As shown in FIG. 19, the semiconductor device according to some embodiments may be turned over, and the substrate 111 may be positioned on a carrier substrate 500. The substrate 111 may be positioned such the upper surface 420a of the upper wiring structures 420 faces the carrier substrate 500, and is attached to the carrier substrate 500. Between the upper surface 420a of the upper wiring structures 420 and the carrier substrate 500, a bonding member may be disposed.

The carrier substrate 500 may have substantially the same area as that of the substrate 111, or may have a larger area. The carrier substrate 500 may be, for example, a semiconductor wafer, a ceramic substrate, or a glass substrate.

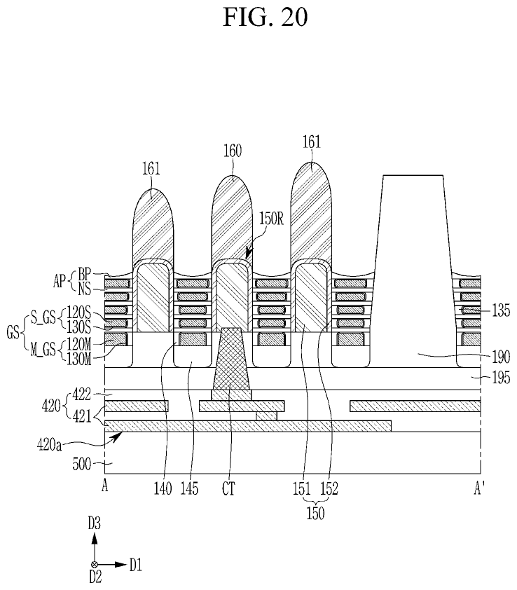

As shown in FIG. 20, the substrate 111 may be removed by performing an etching process. The etching process may be performed, for example, by a dry etching method. In this case, the interlayer insulating layer 190 may include a material having etch selectivity to the substrate 111.

The process of etching the substrate 111 may perform an etching process using an etchant having etch selectivity to the dummy source/drain pattern 160. For example, when the substrate 111 includes silicon (Si) and the dummy source/drain pattern 160 include silicon germanium (SiGe), an etchant having a relatively high etch rate for silicon may be used to perform the etching process.

According to some embodiments, it has been described that the substrate 111 is removed by a dry etching method; however, the present disclosure is not limited thereto, and a wet etching method may be used to remove the substrate 111.

As the substrate 111 is removed, the dummy source/drain pattern 160 and the interlayer insulating layer 190 may be exposed.

At least a portion of the substrate 111 positioned between adjacent source/drain pattern 150 in the first direction D1 may remain to form the lower patterns BP. This is because, as the source/drain pattern 150 and the dummy source/drain pattern 160 protrude in the third direction D3, sufficient spaces for etching the substrate 111 may not be secured between adjacent dummy source/drain pattern 160 in the first direction D1 and between adjacent source/drain pattern 150 in the first direction D1. Thereafter, in the process of etching the substrate 111, at least a portion of the substrate 111 may remain between adjacent source/drain pattern 150 in the first direction D1, to form the lower patterns BP. However, the present disclosure is not limited thereto, and according to some embodiments, the substrate 111 may be removed between adjacent source/drain pattern 150 in the first direction D1, such that the sub-gate structure S_GS are exposed (e.g., FIG. 8).

According to some embodiments, the upper surface of the source/drain pattern 150 may be positioned farther from the upper surface of the carrier substrate 500 than the upper surface of the lower patterns BP are. Accordingly, at least a portion of the side surface of the source/drain pattern 150 may be exposed.

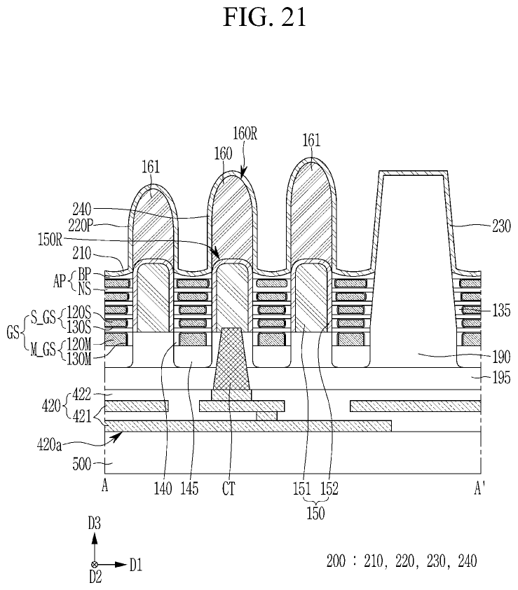

As shown in FIG. 21, the insulating pattern 200 may be formed on the lower patterns BP, the dummy patterns 161, the interlayer insulating layer 190, and the dummy source/drain pattern 160. The insulating pattern 200 may be formed on the lower patterns BP, the dummy patterns 161, the interlayer insulating layer 190, and the dummy source/drain pattern 160 so as to conform to them.

According to some embodiments, the insulating pattern 200 may include a first portion 210 that is positioned on the lower patterns BP, a second preliminary portion 220P that is positioned on the dummy patterns 161, a third portion 230 that is positioned on the interlayer insulating layer 190, and fourth portion 240 that is positioned on the dummy source/drain pattern 160. The first, second, third, and fourth portions 210-240 may be provided in plural, but are described from a singular perspective for ease of description. The dummy patterns 161 may refer to dummy source/drain pattern 160 that are removed in the process of the through-via 300.

According to some embodiments, the upper surface of the first portion 210 may be positioned closer to the upper surface of the carrier substrate 500 than the upper surface of the source/drain pattern 150. Accordingly, the first portion 210 may be positioned between the lower pattern BP and the dummy source/drain pattern 160.

According to some embodiments, the second preliminary portion 220P of the insulating pattern 200 may surround the dummy patterns 161. The second preliminary portion 220P may completely cover the upper surface and side surface of the dummy patterns 161. Also, the second preliminary portion 220P may extend in the third direction D3 and cover at least a portion of the side surface of the source/drain pattern 150. The second preliminary portion 220P may surround at least a portion of the side surface of the source/drain pattern 150.

According to some embodiments, the fourth portion 240 of the insulating pattern 200 may surround the dummy source/drain pattern 160. The fourth portion 240 may completely cover the side surface and upper surfaces of the dummy source/drain pattern 160. Also, the fourth portion 240 may extend in the third direction D3 and cover at least a portion of the side surface of the source/drain pattern 150. The fourth portion 240 may surround at least a portion of the side surface of the source/drain pattern 150.

According to some embodiments, the heights by which the upper surface of the second preliminary portions 220P and the fourth portion 240 extend in the third direction D3 may be different. For example, the upper surface of the second preliminary portions 220P and the upper surface of the fourth portion 240 may have levels different from each other. This is because the insulating pattern 200 are formed on the dummy source/drain pattern 160 having different heights in the third direction D3. Accordingly, distributions of the heights of the second preliminary portions 220P and the fourth portion 240 in the third direction D3 may occur.

The insulating pattern 200 may include various insulating materials. The insulating pattern 200 may include a material having etch selectivity to the insulating layer 100. For example, the insulating pattern 200 may include at least one of silicon nitride (SiN), silicon oxynitride (SiON), silicon carbonitride (SiCN), silicon oxycarbide (SiOC), and silicon oxycarbonitride (SiOCN).

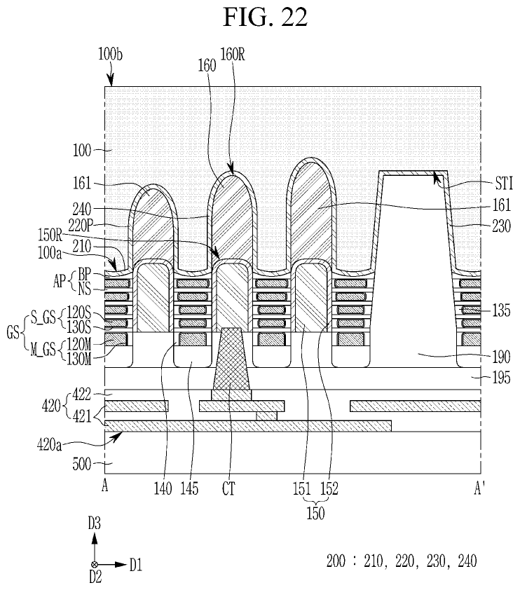

As shown in FIG. 22, the insulating layer 100 may be formed on the insulating pattern 200. For example, the insulating layer 100 may be formed so as to cover the first to fourth portions 210 to 240 of the insulating pattern 200.

The insulating layer 100 may be formed by forming an insulating material layer so as to cover the first to fourth portions 210 to 240 of the insulating pattern 200 and then performing a chemical mechanical polishing (CMP) process of flattening the upper surface of the insulating material layer, but is not limited thereto.

As shown in FIG. 23, first, patterning may be performed on the insulating layer 100 to form first through-holes TH1 that expose at least a portion of the second portion 220. The side surface of the first through-holes TH1 may be formed of, for example, the insulating layer 100. The bottom surfaces of the first through-holes TH1 may be formed of, for example, the insulating layer 100 and the second portion 220.

According to some embodiments, the width of each first through-hole TH1 in the first direction D1 may be greater than the width of each dummy source/drain pattern 160 in the first direction D1. Accordingly, even if there is an error in the process in which the first through-holes TH1 and the second portion 220 are aligned in the third direction D3, the second portion 220 may be exposed.

Subsequently, the exposed second preliminary portion 220P may be removed by performing an etching process, such that the second portion 220 is formed. The etching process may be performed by a wet or dry etching method, but is not limited thereto. In this case, the second portion 220 may include a material having etch selectivity to the insulating layer 100. Accordingly, the dummy patterns 161 may be exposed.

In this case, the upper surface of the second portion 220 may be positioned closer to the upper surface of the carrier substrate 500 than the upper surface of the third portion 230. The height of the second portion in the third direction D3 may be smaller than the height of the third portion 230 in the third direction D3.

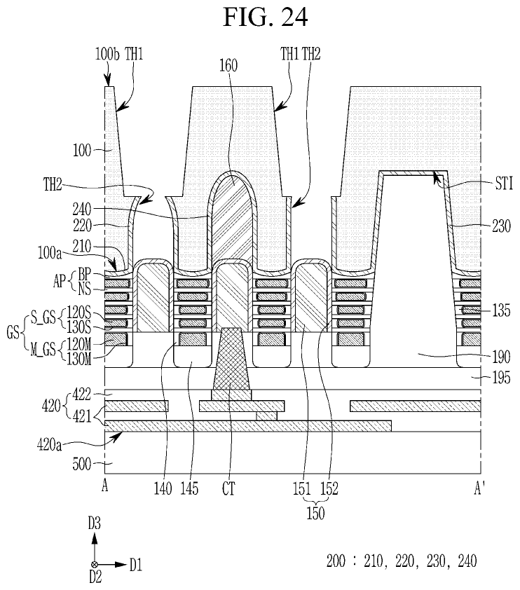

As shown in FIG. 24, the exposed dummy patterns 161 may be removed by performing an etching process, such that second through-holes TH2 are formed.

The etching process may be performed, for example, by a dry etching method, but is not limited thereto. In this case, the dummy patterns 161 may include a material having etch selectivity to the insulating layer 100. The dummy patterns 161 may include a material having etch selectivity to the insulating pattern 200. The dummy patterns 161 may include a material having etch selectivity to the second source/drain pattern 152.

As the dummy patterns 161 are removed, the inner walls of the second portion 220 and the upper surface of the source/drain pattern 150 may be exposed. Since the second portion 220 covers at least a portion of the side surface of the source/drain pattern 150, even when the dummy patterns 161 are removed, the lower patterns BP and/or the sub-gate structure S_GS may not be exposed.

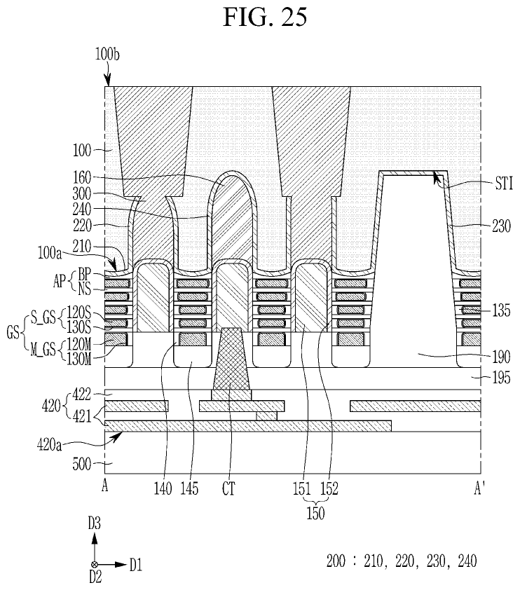

As shown in FIG. 25, the first through-holes TH1 and the second through-holes TH2 may be filled, whereby the through-via 300 may be formed so as to be electrically coupled to the source/drain pattern 150.

In the regions from which the dummy patterns 161 have been removed, the first via portion 310 may be formed, and the first through-holes TH1 may be filled such that the second via portion 320 is formed so as to be electrically coupled to the first via portion 310. The through-via 300 may cover the source/drain pattern 150 and the first through-holes TH1 and the second through-holes TH2 may be filled with the through-via 300.

The through-via 300 may be formed by forming preliminary conductive layers that fill the first through-holes TH1 and the second through-holes TH2 and cover the inner walls of the first through-holes TH1, the inner surfaces of the second through-holes TH2, the bottom surfaces of the second through-holes TH2, and at least a portion of the second surface 100b of the insulating layer 100, and removing the portions of the preliminary conductive layers covering at least a portion of the second surface 100b of the insulating layer 100. The preliminary conductive layers may include, for example, at least one of metals, metal alloys, conductive metal nitrides, conductive metal carbides, conductive metal oxides, and conductive metal carbonitrides.

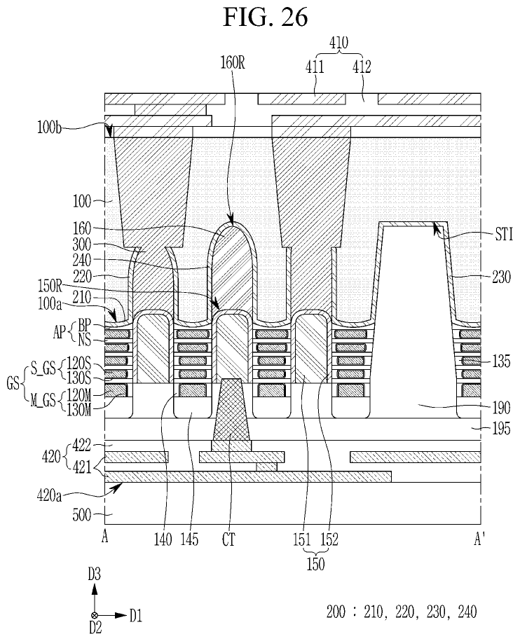

As shown in FIG. 26, the lower wiring structure 410 is formed on the second surface 100b of the insulating layer 100 so as to be electrically coupled to the through-via 300.

The lower wiring structure 410 may include lower wiring lines 411 and a lower wiring insulating layer 412. The lower wiring lines 411 may be positioned on the second surface 100b of the insulating layer 100. The lower wiring lines 411 may include a metal (for example, copper). The lower wiring lines 411 may be electrically coupled to the through-via 300.

The lower wiring insulating layer 412 may be positioned on the second surface 100b of the insulating layer 100. The lower wiring insulating layer 412 may cover the lower wiring structure 410. In other words, the lower wiring insulating layer 412 may cover the lower wiring lines 411, and the lower wiring lines 411 may be disposed in the lower wiring insulating layer 412. The lower wiring insulating layer 412 may include, for example, at least one of silicon oxide (SiO₂), silicon nitride (SiN), silicon oxynitride (SiON), or a low-dielectric constant material.

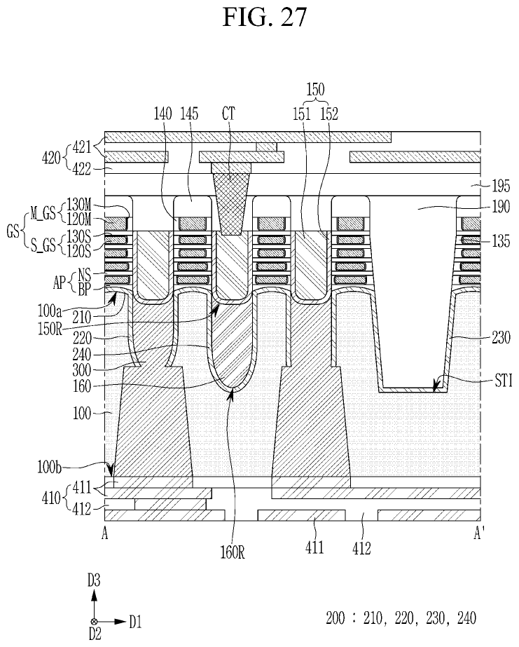

As shown in FIG. 27, after the carrier substrate 500 of the semiconductor device according to some embodiments is removed, the semiconductor device may be turned over, whereby the semiconductor device in FIG. 1 to FIG. 4 may be formed.

In the semiconductor device according to some embodiments, after the insulating pattern 200 are formed on the dummy patterns 161, at least a portion of the insulating pattern 200 may be etched to expose the dummy patterns 161, the exposed dummy patterns 161 may be removed, and the through-via 300 may be formed in the spaces formed by the removal. In other words, the through-via 300 may be formed in the spaces surrounded by the insulating pattern 200. Accordingly, during the process of removing the dummy patterns 161, etching of the surrounding material layers adjacent to the through-via 300 (for example, the insulating layer 100, the lower pattern BP, and/or the sub-gate structure S_GS) may be prevented, and a problem of a short circuit between the through-via 300 and the sub-gate electrodes 120S may be prevented. Therefore, the reliability of the semiconductor device may be improved.

Further, in the semiconductor device according to some embodiments, the first through-holes TH1 may be formed to expose the second portion 220 of the insulating pattern 200 surrounding the dummy source/drain pattern 160. Accordingly, even if a distribution of the lengths of the dummy source/drain pattern 160 in the third direction D3 occurs, the second portion 220 may be exposed by the first through-holes TH1, and the through-via 300 may be formed so as to be coupled to the source/drain pattern 150. Therefore, the reliability of the semiconductor device may be improved.

Furthermore, in the semiconductor device according to some embodiments, the first portion 210 of the insulating pattern 200 may be positioned between the insulating layer 100 and the lower patterns BP, and the second portion 220 of the insulating pattern 200 may cover the side surface of the through-via 300 and at least a portion of the side surface of the source/drain pattern 150.

Accordingly, even when the through-via 300 is formed in the spaces formed by the removal of the dummy patterns 161, the lower pattern BP and the through-via 300 and/or the sub-gate structure S_GS and the through-via 300 may be electrically insulated from each other by the first portion 210 and the second portion 220 of the insulating pattern 200. Therefore, the reliability of the semiconductor device may be improved.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device comprising:
an insulating layer comprising:
a first surface;
a second surface; and
an element isolation trench;
an insulating pattern on the first surface of the insulating layer;
an active pattern on the insulating pattern and comprising a channel pattern;
a source/drain pattern on at least one side of the active pattern;
a lower wiring structure on the second surface of the insulating layer; and
a through-via that extending in the insulating layer and connecting the source/drain pattern and the lower wiring structure,
wherein the insulating pattern comprises:
a first portion between the insulating layer and the active pattern;
a second portion surrounding at least a portion of the through-via; and
a third portion on a bottom surface of the element isolation trench.

2. The semiconductor device of claim 1, wherein the third portion of the insulating pattern is on an inner wall of the element isolation trench, and
wherein a length of the second portion of the insulating pattern in the thickness direction of the insulating layer is smaller than a length of the third portion of the insulating pattern in the thickness direction of the insulating layer.

3. The semiconductor device of claim 2, wherein a lower surface of the first portion of the insulating pattern is farther from the second surface of the insulating layer than a lower surface of the source/drain pattern is from the second surface of the insulating layer.

4. The semiconductor device of claim 1, wherein the second portion of the insulating pattern contacts at least a portion of a side surface of the source/drain pattern.

5. The semiconductor device of claim 1, wherein the through-via comprises:
a first via portion at least partially surrounded by the second portion of the insulating pattern; and
a second via portion between the first via portion and the lower wiring structure.

6. The semiconductor device of claim 5, wherein a width of the second via portion is greater than a width of the first via portion.

7. The semiconductor device of claim 5, wherein at least a portion of the second portion of the insulating pattern extends over the second via portion in a direction parallel with the second surface of the insulating layer, and
wherein at least another portion of the second portion of the insulating pattern does not extend over the second via portion in the direction parallel with the second surface of the insulating layer.

8. The semiconductor device of claim 1, further comprising:
a gate structure on the insulating pattern and at least partially surrounding the channel pattern,
wherein the active pattern further comprises a lower pattern between the first portion of the insulating pattern and the gate structure.

9. The semiconductor device of claim 8, further comprising:
a dummy source/drain pattern below the source/drain pattern,
wherein the insulating pattern further comprises a fourth portion at least partially surrounding the dummy source/drain pattern.

10. The semiconductor device of claim 9, wherein an upper surface of the dummy source/drain pattern is closer to the second surface of the insulating layer than a lower surface of the gate structure is from the second surface of the insulating layer.

11. The semiconductor device of claim 1, further comprising:
a gate structure on the insulating pattern and at least partially surrounding the channel pattern,
wherein the first portion of the insulating pattern contacts the gate structure.

12. The semiconductor device of claim 1, wherein the insulating pattern comprises a material having etch selectivity to the insulating layer.

13. The semiconductor device of claim 12, wherein the insulating pattern comprises at least one of SiN, SiON, SiCN, SiOC, SiOCN, and metal oxides.

14. The semiconductor device of claim 1, wherein the insulating pattern further comprises:
an outer insulating pattern contacting the insulating layer; and
an inner insulating pattern on the outer insulating pattern, and wherein the inner insulating pattern comprises at least one of SiN, SiON, SiCN, SiOC, SiOCN, AlN, and Al₂O₃.

15. A semiconductor device comprising:
an insulating layer comprising a first surface and a second surface;
an insulating pattern on the first surface of the insulating layer;
an active pattern on the insulating pattern and comprising a channel pattern;
a source/drain pattern on at least one side of the active pattern;
a dummy source/drain pattern extending in at least a portion of the insulating pattern and positioned below the source/drain pattern;
a lower wiring structure below the second surface of the insulating layer; and
a through-via extending in the insulating layer and connecting the source/drain pattern and the lower wiring structure,
wherein the insulating pattern comprises:
a first portion between the insulating layer and the active pattern;
a second portion surrounding at least a portion of the through-via; and
a fourth portion at least partially surrounding the dummy source/drain pattern.

16. The semiconductor device of claim 15, wherein a length of the fourth portion of the insulating pattern in the thickness direction of the insulating layer is greater than a length of the second portion of the insulating pattern in the thickness direction of the insulating layer.

17. The semiconductor device of claim 15, wherein the second portion of the insulating pattern contacts at least a portion of a side surface of the source/drain pattern.

18. The semiconductor device of claim 15, wherein a lower surface of the first portion of the insulating pattern is farther from the second surface of the insulating layer than a lower surface of the source/drain pattern is from the second surface of the insulating layer.

19. A semiconductor device comprising:
an insulating layer comprising:
a first surface;
a second surface facing; and
an element isolation trench;
an insulating pattern on the first surface of the insulating layer;
an active pattern on the insulating pattern and comprising a channel pattern;
a source/drain pattern on at least one side of the active pattern;
a dummy source/drain pattern extending in at least a portion of the insulating pattern and below the source/drain pattern;
a gate electrode on the insulating pattern and at least partially surrounding the channel pattern;
a lower wiring structure below the second surface of the insulating layer; and
a through-via extending in the insulating layer and connecting the source/drain pattern and the lower wiring structure,
wherein the insulating pattern comprises:
a first portion between the insulating layer and the gate electrodes;
a second portion surrounding at least a portion of the through-via;
a third portion on inner walls and bottom surfaces of the element isolation trench; and
a fourth portion at least partially surrounding the dummy source/drain pattern, and
wherein the through-via comprises:
a first via portion at least partially surrounded by the second portion of the insulating pattern; and
a second via portion between the first via portion and the lower wiring structure.

20. The semiconductor device of claim 19, wherein a length of the second portion of the insulating pattern in the thickness direction of the insulating layer is smaller than a length of the third portion of the insulating pattern in the thickness direction of the insulating layer.
